(19) United States
(12) Patent Application Publication
(10) Pub. No.: US 2025/0120259 A1
(43) Pub. Date: Apr. 10, 2025

(54) SUB-PIXEL AND DISPLAY DEVICE INCLUDING THE SAME

(71) Applicant: Samsung Display Co., Ltd., Yongin-Si (KR)

(72) Inventors: Sung Chul HONG, Yongin-si (KR); Kyung Bae KIM, Yongin-si (KR); Do Yeong PARK, Yongin-si (KR)

(21) Appl. No.: 18/756,130

(22) Filed: Jun. 27, 2024

(30) Foreign Application Priority Data
Oct. 5, 2023 (KR) 10-2023-0132771

(51) Int. Cl. H10K 59/121; H10K 59/131

(52) U.S. Cl. CPC H10K 59/1216; H10K 59/1213; H10K 59/131

(57) ABSTRACT

There are provided a sub-pixel and a display device including the same, which can increase the capacitance of a capacitor. The sub-pixel may include a first capacitor including a first electrode connected to a first power line and a second electrode connected to a second node. The second electrode may be directly connected to a semiconductor layer of a first transistor, a semiconductor layer of a third transistor, and a semiconductor layer of a fourth transistor.

### CROSS-REFERENCE TO RELATED APPLICATION

The present application claims priority under 35 U.S.C. § 119 (a) to Korean patent application No. 10-2023-0132771 filed on Oct. 5, 2023, in the Korean Intellectual Property Office, the entire disclosure of which is incorporated herein by reference.

### BACKGROUND

### 1. Technical Field

The present disclosure generally relates to a sub-pixel and a display device including the same.

### 2. Related Art

With the development of information technologies, the importance of a display device which is a connection medium between a user and information increases. Accordingly, display devices such as a liquid crystal display device, an organic light emitting display device, and an inorganic light emitting display device are increasingly used.

As display devices are miniaturized, the size of pixels (or sub-pixels) for displaying images in the display devices also becomes smaller. Accordingly, the size of each of circuit elements constituting the pixel also becomes smaller.

Among the circuit elements, the capacitance of a capacitor is in proportion to the size of an electrode. As the size of the circuit element becomes smaller, the size of the electrode constituting the capacitor also becomes smaller, and therefore, the capacitance of the capacitor may decrease. Accordingly, a structure to enhance the capacitance of the capacitor in a restricted area is required.

### SUMMARY

Embodiments provide a sub-pixel having a large capacitance of a capacitor and a display device including the sub-pixel.

In accordance with an aspect of the present disclosure, there is provided a sub-pixel including: a light emitting element; a first transistor connected between a first power line and a first node, the first transistor including a gate electrode connected to a second node; a second transistor connected to a data line, the second transistor including a gate electrode connected to a first sub-gate line, the second transistor receiving a data signal supplied from the data line in response to a first scan signal supplied from the first sub-gate line; a third transistor including a gate electrode connected to a third sub-gate line, the third transistor switching electrical connection between the first node and the second node in response to a third scan signal supplied from the third sub-gate line; a fourth transistor including a gate electrode connected to a second sub-gate line, the fourth transistor switching electrical connection between the second node and a third power line in response to a second scan signal supplied from the second sub-gate line; a fifth transistor including a gate electrode connected to an emission control line, the fifth transistor switching electrical connection between the first node and the light emitting element in response to an emission control signal supplied from the emission control line; and a first capacitor including a first electrode connected to the first power line and a second electrode connected to the second node, wherein the second electrode is directly connected to the gate electrode of the first transistor, a semiconductor layer of the third transistor, and a semiconductor layer of the fourth transistor.

The semiconductor layer of the third transistor and the semiconductor layer of the fourth transistor may be integrally formed.

The first to third sub-gate lines and the emission control line may include a first metal layer extending in a first direction. Each of the first electrode of the first capacitor and the second electrode of the first capacitor may include the first metal layer.

The gate electrode of each of the first to fifth transistors may include a gate electrode layer. An interlayer insulating layer may be interposed between the gate electrode layer and the first metal layer. The first metal layer may be directly connected to the gate electrode layer through a first contact portion formed in the interlayer insulating layer.

The first metal layer constituting the first electrode and the second electrode of the first capacitor may extend in the first direction in an area overlapping with the gate electrode of the first transistor to face each other in a plan view. The first electrode of the first capacitor and the second electrode of the first capacitor may be interdigitated each other along the second direction.

The first power line, the third power line, and the data line may include a second metal layer extending in a second direction. Each of the first electrode of the first capacitor and the second electrode of the first capacitor may include the second metal layer.

A first via layer may be interposed between the first metal layer and the second metal layer. The second metal layer may be directly connected to the first metal layer at a second contact portion formed through the first via layer.

At least a portion of the second metal layer constituting the first capacitor may overlap at least a portion of the first metal layer constituting the first capacitor in a plan view.

The sub-pixel may further include a second capacitor including one electrode connected to the second transistor and the other electrode connected to the second node.

Each of the one electrode of the second capacitor and the other electrode of the second capacitor may include a third metal layer located on the second metal layer.

Each of the first electrode of the first capacitor and the second electrode of the first transistor may include the third metal layer.

A second via layer may be interposed between the second metal layer and the third metal layer. The third metal layer may be directly connected to the second metal layer at a third contact portion formed through the second via layer.

The third metal layer constituting the first electrode of the first capacitor may be directly connected to the second metal layer constituting the first power line through the third contact portion.

The third metal layer constituting the second electrode of the first capacitor may be directly connected to the second metal layer constituting the second node through the third contact portion.

The gate electrode of each of the first to fifth transistors may include a gate electrode layer. The first to third sub-gate lines and the emission control line may include the gate electrode layer extending in a first direction.

Each of the first electrode of the first capacitor and the second electrode of the first capacitor may include a first metal layer. An interlayer insulating layer may be interposed between the first metal layer and the gate electrode layer. The first metal layer may be directly connected to the gate electrode layer at a first contact portion formed through the interlayer insulating layer.

Each of the first electrode of the first capacitor and the second electrode of the first capacitor may overlap with a semiconductor layer of each of the first to fifth transistors in a plan view.

In accordance with another aspect of the present disclosure, there is provided a display device including: a substrate and a plurality of sub-pixels disposed on the substrate. Each of the plurality of sub-pixels may include a pixel circuit layer disposed on the substrate, the pixel circuit layer having a sub-pixel circuit of each of the plurality of sub-pixels; and a light emitting element layer disposed on the pixel circuit layer, the light emitting element layer having a light emitting element of each of the plurality of sub-pixels, wherein the pixel circuit layer includes: a semiconductor layer; a gate insulating layer disposed on the semiconductor layer; a gate electrode layer disposed on the gate insulating layer; an interlayer insulating layer disposed on the gate electrode layer, the interlayer insulating layer including a first contact portion; and a first metal layer disposed on the interlayer insulating layer, the first metal layer being directly connected to the gate electrode layer through the first contact portion, the first metal layer constituting a capacitor included in the sub-pixel circuit.

The sub-pixel circuit may include: a first transistor connected between a first power line and a first node, the first transistor including a gate electrode connected to a second node; a second transistor connected to a data line, the second transistor including a gate electrode connected to a first sub-gate line, the second transistor receiving a data signal supplied from the data line in response to a first scan signal supplied from the first sub-gate line; a third transistor including a gate electrode connected to a third sub-gate line, the third transistor switching electrical connection between the first node and the second node in response to a third scan signal supplied from the third sub-gate line; a fourth transistor including a gate electrode connected to a second sub-gate line, the fourth transistor switching electrical connection between the second node and a third power line in response to a second scan signal supplied from the second sub-gate line; a fifth transistor including a gate electrode connected to an emission control line, the fifth transistor switching electrical connection between the first node and the light emitting element in response to an emission control signal supplied from the emission control line; and the capacitor including a first electrode connected to the first power line and a second electrode connected to the second node, wherein the second electrode is directly connected to the gate electrode of the first transistor, a semiconductor layer of the third transistor, and a semiconductor layer of the fourth transistor.

The gate electrode of each of the first to fifth transistors may include a gate electrode layer. A first sub-pixel and a second sub-pixel among the plurality of sub-pixels may be located adjacent to each other in a first direction. The gate electrode layer may extend in the first direction to be commonly connected to the first sub-pixel and the second sub-pixel.

The display device may further include a gate driving circuit configured to supply scan signals to the first to third sub-gate lines, and supply an emission control signal to the emission control line. The gate electrode layer may be directly connected to the gate driving circuit.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a system block diagram of a display device in accordance with embodiments of the present disclosure.

FIG. 2 is a block diagram illustrating an embodiment of any one of sub-pixels shown in FIG. 1.

FIG. 3 is an equivalent circuit diagram illustrating an embodiment of the sub-pixel shown in FIG. 2.

FIG. 4 is a view illustrating a semiconductor layer and a gate electrode layer of a sub-pixel in accordance with embodiments of the present disclosure.

FIG. 5 is a view illustrating the semiconductor layer, the gate electrode layer, a first contact portion, and a first metal layer of the sub-pixel in accordance with embodiments of the present disclosure.

FIG. 6 is a view illustrating the first metal layer, a second contact portion, and a second metal layer of the sub-pixel in accordance with embodiments of the present disclosure.

FIG. 7 is a view illustrating the second metal layer, a third contact portion, and a third metal layer of the sub-pixel in accordance with embodiments of the present disclosure.

FIG. 8 is a view illustrating a third metal layer, a fourth contact portion, and a fourth metal layer of the sub-pixel in accordance with embodiments of the present disclosure.

FIG. 9 is a view illustrating a semiconductor layer and a gate electrode layer of a sub-pixel in accordance with other embodiments of the present disclosure.

FIG. 10 is a view illustrating the semiconductor layer, the gate electrode layer, a first contact portion, and a first metal layer of the sub-pixel in accordance with other embodiments of the present disclosure.

FIG. 11 is a plan view illustrating an embodiment of a display panel shown in FIG. 1.

FIG. 12 is an exploded perspective view illustrating a portion of the display panel shown in FIG. 11.

FIG. 13 is a plan view illustrating an embodiment of any one of pixels shown in FIG. 12.

FIG. 14 is a diagram illustrating an embodiment of a display system in accordance with embodiments of the present disclosure.

FIG. 15 is a perspective view illustrating an application example of the display system shown in FIG. 14.

FIG. 16 is a view illustrating a head-mounted display device worn by a user.

### DETAILED DESCRIPTION

Hereinafter, exemplary embodiments are described in detail with reference to the accompanying drawings so that those skilled in the art may easily practice the present disclosure. The present disclosure may be implemented in various different forms and is not limited to the exemplary embodiments described in the present specification.

A part irrelevant to the description will be omitted to clearly describe the present disclosure, and the same or similar constituent elements will be designated by the same reference numerals throughout the specification. Therefore, the same reference numerals may be used in different drawings to identify the same or similar elements.

In addition, the size and thickness of each component illustrated in the drawings are arbitrarily shown for better understanding and ease of description, but the present disclosure is not limited thereto. Thicknesses of several portions and regions are exaggerated for clear expressions.

In description, the expression “equal” may mean “substantially equal.” That is, this may mean equality to a degree to which those skilled in the art can understand the equality. Other expressions may be expressions in which “substantially” is omitted.

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the present disclosure. As used herein, the singular forms are intended to include the plural forms as well, unless the context clearly indicates otherwise.

The terms “under,” “beneath,” “on,” “above,” and the like are used to describe a relationship between components illustrated in a drawing. The terms are relative and are described with reference to a direction indicated in the drawing.

Unless defined otherwise, it is to be understood that all the terms (including technical and scientific terms) used in the specification has the same meaning as those that are understood by those who skilled in the art. Further, the terms defined by the dictionary generally used should not be ideally or excessively formally defined unless clearly defined specifically.

It will be further understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof.

Hereinafter, exemplary embodiments of the present disclosure will be described in detail with reference to the accompanying drawings.

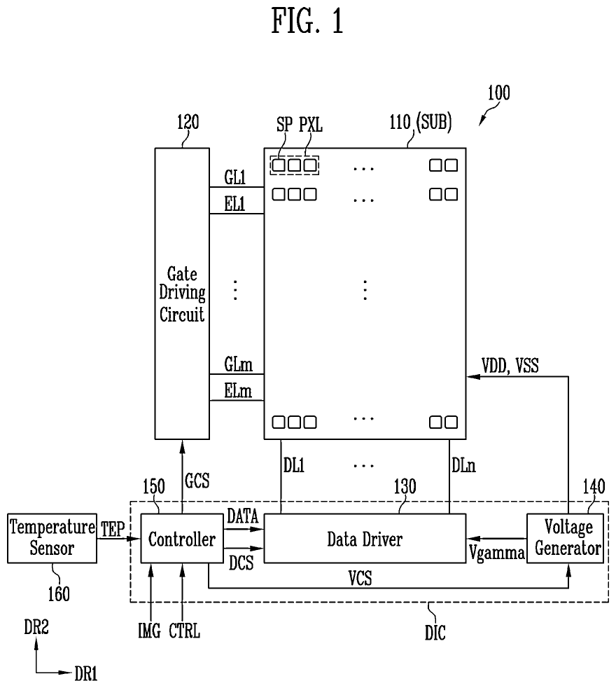

FIG. 1 is a system block diagram of a display device 100 in accordance with embodiments of the present disclosure.

Referring to FIG. 1, the display device 100 in accordance with the embodiments of the present disclosure may include a display panel 110, a gate driving circuit 120, a data driver 130, a voltage generator 140, a controller 150, a temperature sensor 160, and the like.

The display panel 110 may include a plurality of sub-pixels SP. First to mth gate lines GL1 to GLm (m is an integer of 2 or more) connected to the plurality of sub-pixels SP may be disposed in the display panel 110. First to nth data lines DL1 to DLn (n is an integer of 2 or more) connected to the plurality of sub-pixels SP may be disposed in the display panel 110.

The plurality of sub-pixels SP may be connected (e.g., electrically connected) to the gate driving circuit 120 through the first to mth gate lines GL1 to GLm. The plurality of sub-pixels SP may be connected (e.g., electrically connected) to the data driver 130 through the first to nth data lines DL1 to DLn.

Each of the plurality of sub-pixels SP may include at least one light emitting element configured to generate light. Each of the plurality of sub-pixels SP may generate light of a color (e.g., a specific color or a specific wavelength band) such as red, green, blue, cyan, magenta or yellow. Two or more sub-pixels among the plurality of sub-pixels SP may constitute one pixel PXL. For example, three sub-pixels SP may constitute one pixel PXL as shown in FIG. 1.

The gate driving circuit 120 may be connected (e.g., electrically connected) to the plurality of sub-pixels SP (e.g., the plurality of sub-pixels SP entirely arranged in a first direction DR1) through the first to mth gate lines GL1 to GLm. The first direction DR1 may be, for example, a direction crossing the display panel 110 from one side (e.g., a left side) to the other side (e.g., a right side) of the display panel 110. The first direction DR1 may be, for example, a row direction.

The gate driving circuit 120 may output gate signals (e.g., gate signals having a turn-on level or a turn-off level) to the first to mth gate lines GL1 to GLm in response to a gate control signal GCS. In embodiments, the gate control signal GCS may include a start signal indicating a start of each frame, a horizontal synchronization signal for outputting gate signals in synchronization with timings at which data signals are applied, and the like.

In embodiments, first to mth emission control lines EL1 to ELm connected to the plurality of sub-pixels SP may be further disposed in the display panel 110. The first to mth emission control lines EL1 to ELm may be disposed in the display panel 110 while extending in the row direction. The plurality of sub-pixels SP may be connected (e.g., electrically connected) to the first to mth emission control lines EL1 to ELm. In the above embodiment, the gate driving circuit 120 may include an emission control driver configured to control the first to mth emission control lines EL1 to ELm. The emission control driver may operate under the control of the controller 150.

The gate driving circuit 120 may be disposed at one side of the display panel 110. However, embodiments of the present disclosure are not limited thereto. For example, the gate driving circuit 120 may include two or more driving circuits which are physically divided, and these driving circuits may be disposed at one side of the display panel 110 and the other side of the display panel 110 (e.g., the other side of the display panel 110, which faces the one side of the display panel 110). As such, in some embodiments, the gate driving circuit 120 may be disposed in various forms in the display panel 110 or at the periphery of the display panel 110.

The data driver 130 may be connected (e.g., electrically connected) to the plurality of sub-pixels SP (e.g., the plurality of sub-pixels SP entirely arranged in a second direction DR2) through the first to nth data lines DL1 to DLn. The second direction DR2 may be, for example, a direction crossing the display panel 110 from one side (e.g., a lower side) of the display panel 110 to the other side (e.g., an upper side) of the display panel 110. The second direction DR2 may be, for example, a column direction.

The data driver 130 may receive image data DATA and a data control signal DCS from the controller 150. The data driver 130 may operate in response to the data control signal DCS. In embodiments, the data control signal DCS may include a source start pulse, a source shift clock, a source output enable signal, and the like.

The data driver 130 may apply data signals having grayscale voltages corresponding to the image data DATA to the first to nth data lines DL1 to DLn by using voltages (e.g., gamma voltages Vgamma) from the voltage generator 140. When a gate signal (e.g., a gate signal having the turn-on level) is applied to each of the first to mth gate lines GL1 to GLm, data signals corresponding to the image data DATA may be applied to the data line DL1 to DLm. Each of the plurality of sub-pixels SP may receive a data signal applied at a corresponding timing in response to the gate signal (e.g., the gate signal having the turn-on level). Each of the plurality of sub-pixels SP may generate light corresponding to the received data signal. Accordingly, an image may be displayed in on the display panel 110.

In embodiments, each of the gate driving circuit 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device 100. For example, the voltage generator 140 may receive an input voltage from the outside of the display device 100. The voltage generator 140 may adjust (e.g., decrease) a level of the received voltage, and regulate the voltage having the adjusted level. The voltage generator 140 may be configured to generate a plurality of voltages.

The voltage generator 140 may generate, for example, a first power voltage VDD, a second power voltage VSS, a gamma voltage Vgamma, and the like. The generated first and second power voltages VDD and VSS may be applied (e.g., commonly applied) to the plurality of sub-pixels SP. The first power voltage VDD may have a relatively high voltage level. The second power voltage VSS may have a voltage level lower than the voltage level of the first power voltage VDD. The generated gamma voltage Vgamma may be provided to the data driver 130. In other embodiments, the first power voltage VDD and/or the second power voltage VSS may be provided by an external device of the display device 100 (e.g., a Power Management Integrated Circuit (PMIC)).

In some embodiments, the voltage generator 140 may further generate another voltage. For example, the voltage generator 140 may generate an initialization voltage applied (e.g., commonly applied) to the plurality of sub-pixels SP. For example, in a sensing operation for sensing electrical characteristics of transistors and/or a light emitting element(s) of the plurality of sub-pixels SP, a predetermined reference voltage may be applied to the first to nth data lines DL1 to DLn, and the voltage generator 140 may generate the reference voltage.

The controller 150 may be configured to control overall operations of the display device 100. The controller 150 may receive, from the outside, input image data IMG and a control signal CTRL for controlling the display device 100. The controller 150 may provide the gate control signal GCS, the data control signal DCS, the voltage control signal VCS, and the like in response to the received control signal CTRL.

The controller 150 may convert the input image data IMG to be suitable for the display device 100 or the display panel 110, thereby outputting the image data DATA. In embodiments, the controller 150 may align the input image data IMG to be suitable for the sub-pixels SP in units of rows, thereby outputting the image data DATA.

Two or more components among the data driver 130, the voltage generator 140, and the controller 150 may be mounted on one integrated circuit. As shown in FIG. 1, the data driver 130, the voltage generator 140, and the controller 150 may be included in a driver integrated circuit DIC. The data driver 130, the voltage generator 140, and the controller 150 may be components functionally divided in one driver integrated circuit DIC. In other embodiments, at least one of the data driver 130, the voltage generator 140, and the controller 150 may be integrated into the driver integrated circuit DIC, and another of the data driver 130, the voltage generator 140, and the controller 150 may be integrated into an integrated circuit different from the driver integrated circuit DIC.

The temperature sensor 160 may be configured to sense a temperature (e.g., a temperature at the periphery thereof) and generate temperature data TEP indicating the sensed temperature. In some embodiments, the temperature sensor 160 may be disposed in the display panel 110. In some embodiments, the temperature sensor 160 may be disposed to be adjacent to the display panel 110 and/or the driver integrated circuit DIC. In some embodiments, the display device 100 may include two or more temperature sensors 160.

The controller 150 may control various operations of the display device 100 in response to the temperature data TEP. In embodiments, the controller 150 may adjust a luminance of an image output from the display panel 110 in response to the temperature data TEP. For example, the controller 150 may control components such as the data driver 130 and/or the voltage generator 140, thereby adjusting at least one of the data signals, the first power voltage VDD, and the second power voltage VSS which are input to the display panel 110.

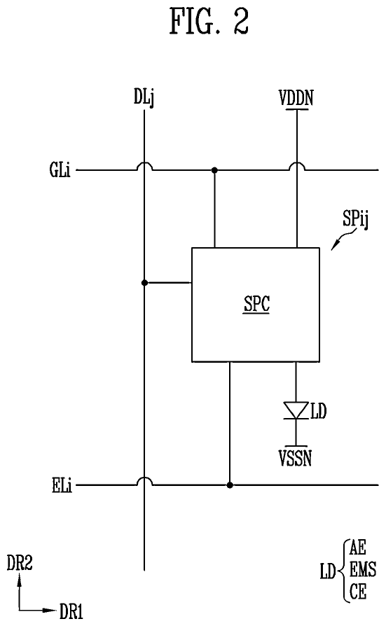

FIG. 2 is a block diagram illustrating an embodiment of any one of the sub-pixels SP shown in FIG. 1.

In FIG. 2, a sub-pixel SPij disposed on an ith row (i is an integer of 1 or more and

m or less) and a jth column (j is an integer of 1 or more and n or less) among the plurality of sub-pixels SP shown in FIG. 1 is exemplarily illustrated.

Referring to FIG. 2, the sub-pixel SPij may include a sub-pixel circuit SPC and a light emitting element LD.

The light emitting element LD may be connected (e.g., electrically connected) between a first power voltage node VDDN and a second power voltage node VSSN. The first power voltage node VDDN may be a node to which the first power voltage VDD shown in FIG. 1 is applied. The second power voltage node VSSN may be a node to which the second power voltage VSS shown in FIG. 1 is applied.

The light emitting element LD may include a first electrode, a light emitting structure EMS, and a second electrode. The first electrode may be any one of an anode electrode AE and a cathode electrode CE of the light emitting element LD. The second electrode may be the other of the anode electrode AE and the cathode electrode CE of the light emitting element LD. Hereinafter, for convenience of description, a case where the first electrode of the light emitting element LD is the anode electrode AE and the second electrode of the light emitting element LD is the cathode electrode CE is described as an example.

The anode electrode AE of the light emitting element LD may be connected (e.g.,

electrically connected) to the first power voltage node VDDN through the sub-pixel circuit SPC. The cathode electrode CE of the light emitting element LD may be connected (e.g., electrically connected) to the second power voltage node VSSN. For example, the anode electrode AE of the light emitting element LD may be connected (e.g., electrically connected) to the first power voltage node VDDN through one or more transistors included in the sub-pixel circuit SPC.

The sub-pixel circuit SPC of the sub-pixel SPij may be connected (e.g., electrically connected) to an ith gate line GLi among the first to mth gate lines GL1 to GLm shown in FIG. 1. The sub-pixel circuit SPC of the sub-pixel SPij may be connected (e.g., electrically connected) to an ith emission control line ELi among the first to mth emission control lines EL1 to Elm shown in FIG. 1. The sub-pixel circuit SPC of the sub-pixel SPij may be connected (e.g., electrically connected) to a jth data line DLj among the first to nth data lines DL1 to DLn shown in FIG. 1. The sub-pixel circuit SPC may be configured to control an emission timing and/or an emission luminance of the light emitting element LD according to (or in response to) signals received through these signal lines.

The sub-pixel circuit SPC may operate in response to a gate signal received through the ith gate line GLi. The sub-pixel SPC may operate in response to an emission control signal received through the ith emission control line ELi.

The sub-pixel circuit SPC may receive a data signal through a jth data line DLj. The sub-pixel circuit SPC may store a voltage of the data signal (or a voltage corresponding to the data signal) in response to the gate signal (e.g., the gate signal having the turn-on level) received through the ith gate line GLi. The sub-pixel circuit SPC may adjust a timing at which a current flows through the light emitting element LD in response to the emission control signal (e.g., the emission control having the turn-on level) applied through the ith emission control line ELi. A magnitude of the current flowing through the light emitting element LD may vary according to a voltage stored in the sub-pixel circuit SPC. The light emitting element LD may generate light with a luminance corresponding to the data signal.

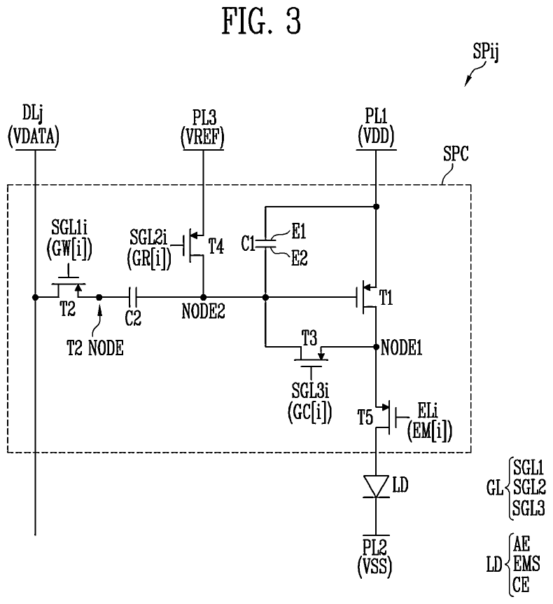

FIG. 3 is an equivalent circuit diagram illustrating an embodiment of the sub-pixel SPij shown in FIG. 2.

Referring to FIG. 3, the sub-pixel SPij in accordance with the embodiments of the present disclosure may include a sub-pixel circuit SPC and a light emitting element LD.

The sub-pixel circuit SPC may be connected (e.g., electrically connected) to an ith gate line GLi (hereinafter, abbreviated as a gate line GLi), an ith emission control line ELi (hereinafter, abbreviated as an emission control line ELi), and a jth data line DLj (hereinafter, abbreviated as a data line DLj).

The gate line GLi may include two or more sub-gate lines. Referring to FIG. 3, the gate line GLi may include a first sub-gate line SGL1i (or abbreviated as a first sub-gate line SGL1), a second sub-gate line SGL2i (or abbreviated as a second sub-gate line SGL2), and a third sub-gate line SGL3i (or abbreviated as a third sub-gate line SGL3).

The sub-pixel circuit SPC may include two or more switching elements (e.g., transistors) and one or more storage elements (e.g., capacitors). Referring to FIG. 3, the sub-pixel circuit SPC in accordance with the embodiments of the present disclosure may include first to fifth transistors T1 to T5 and first and second capacitors C1 and C2.

The first transistor T1 may be configured to switch electrical connection between a first power line PL1 and a first node NODE1. The first power line PL1 may be a line to which a first power voltage VDD is transferred. The first transistor T1 may include a gate electrode connected (e.g., electrically connected) to a second node NODE2. A current (e.g., a driving current) having a magnitude corresponding to a voltage applied to the second node NODE2 may flow through the first transistor T1. The first power voltage VDD may be applied to a body electrode of the first transistor T1.

The second transistor T2 may be configured to switch electrical connection between the data line DLj and the second capacitor C2. A gate electrode of the second transistor T2 may be connected (e.g., electrically connected) to the first sub-gate line SGL1i. An operation timing of the second transistor T2 may be controlled by a first scan signal GW[i] supplied from the first sub-gate line SGL1i. The second transistor T2 may electrically connect the data line DLj to the second capacitor C2 in response to the first scan signal GW[i] having a turn-on level. When the second transistor T2 is turned on, a data signal VDATA may be input to the second capacitor C2.

The third transistor T3 may be configured to switch electrical connection between the first node NODE1 and the second node NODE2. A gate electrode of the third transistor T3 may be connected (e.g., electrically connected) to the third sub-gate line SGL3i. An operation timing of the third transistor T3 may be controlled by a third scan signal GC[i] supplied from the third sub-gate line SGL3i. The third transistor T3 may electrically connect the first node NODE1 to the second node NODE2 in response to the third scan signal GC[i] having the turn-on level. When the third transistor T3 is turned on, the first transistor T1 may be diode-connected.

The fourth transistor T4 may be configured to switch electrical connection between the second node NODE2 and a third power line PL3. A third power voltage VREF may be supplied from the third power line PL3. The third power voltage VREF may be provided from, for example, the power generator 140 (see FIG. 1). A gate electrode of the fourth transistor T4 may be connected (e.g., electrically connected) to the second sub-gate line SGL2i. An operation timing of the fourth transistor T4 may be controlled by a second scan signal GR[i] supplied from the second sub-gate line SGL2i. The fourth transistor T4 may electrically connect the third power line PL3 to the second node NODE2 in response to the second scan signal GR[i] having the turn-on level. When the fourth transistor T4 is turned on, the voltage of the second node NODE2 may be initialized to the third power voltage VREF.

The fifth transistor T5 may be configured to switch electrical connection between the first node NODE1 and the light emitting element LD. A gate electrode of the fifth transistor T5 may be connected (e.g., electrically connected) to the emission control line ELi. An operation timing of the fifth transistor T5 may be controlled by an emission control signal EM[i] supplied from the emission control line ELi. The fifth transistor T5 may electrically connect the first node NODEI to the light emitting element LD in response to the emission control signal EM[i] having the turn-on level. When the fifth transistor T5 is turned on, a current (e.g., a driving current) may flow through the light emitting element LD.

The first capacitor C1 may be configured to maintain a potential difference between the second node NODE2 and the first power line PL1. The first capacitor C1 may be connected between the first power line PL1 and the second node NODE2. The first capacitor C1 may include a first electrode E1 connected (e.g., electrically connected) to the first power line PL1 and a second electrode E2 connected (e.g., electrically connected) to the second node NODE2. The first electrode E1 and the second electrode E2 may be disposed to face each other. A quantity of charges to be stored in the first capacitor C1 (or a capacitor of the first capacitor C1) may vary according to an area in which the first electrode E1 and the second E2 overlaps each other. For example, when the area in which the first electrode E1 and the second electrode E2 overlap with each other while being opposite to each other is large, the quantity of charges to be stored in the first capacitor C1 may be relatively large.

The second capacitor C2 may be connected between the second transistor T2 and the second node NODE2. The second capacitor C2 may include one electrode connected to the second transistor T2 and the other electrode connected to the second node NODE2. The data signal VDATA or a voltage corresponding thereto may be applied to the one electrode of the second capacitor C2. The third power voltage VREF may be applied to the other electrode of the second capacitor C2. When the data signal VDATA is input to the one electrode of the second transistor C2, the voltage of the second node NODE2 may be changed from the third power voltage VREF by a coupling effect of the second capacitor C2.

Referring to FIG. 3, each of the first to fifth transistors T1 to T5 may be a P-type transistor (e.g., a transistor including a P-type semiconductor). However, embodiments of the present disclosure are not limited thereto. For example, at least one of the first to fifth transistors T1 to T5 may be implemented as an N-type transistor (e.g., a transistor including an N-type semiconductor). At least one of the first to fifth transistors T1 to T5 may be a Metal Oxide Semiconductor Field Effect Transistor (MOSFET).

In embodiments, each of the first to fifth transistors T1 to T5 may include a semiconductor layer. The semiconductor layer of each of the first to fifth transistors T1 to T5 may include an amorphous silicon semiconductor, a polycrystalline silicon semiconductor, an oxide semiconductor, and the like.

The light emitting element LD may include an anode electrode AE, a cathode electrode CE, and a light emitting structure EMS. The anode electrode AE of the light emitting element LD may be connected (e.g., electrically connected) to the fifth transistor T5. The cathode electrode CE of the light emitting element LD may be connected (e.g., electrically connected) to a second power line PL2. A second power voltage VSS may be supplied from the second power line PL2. The light emitting structure EMS may be disposed between the anode electrode AE and the cathode electrode CE. The data signal VDATA written to the sub-pixel SPij through the data line DLj may be changed to the voltage of the second node NODE2 by the coupling effect of the second capacitor C2. When the emission control signal EM[i] is enabled to the turn-on level (e.g., a low level), the fifth transistor T5 may be turned on. The first transistor T1 may be turned on according to the voltage of the second node NODE2, and a current (e.g., a driving current) having a magnitude corresponding to the voltage of the second NODE2 may flow through the first transistor T1. Accordingly, the current may flow from the first power line PL1 to the second power line PL2. The light emitting element LD may emit light with a luminance corresponding to the magnitude of the current (e.g., the driving current) flowing therethrough.

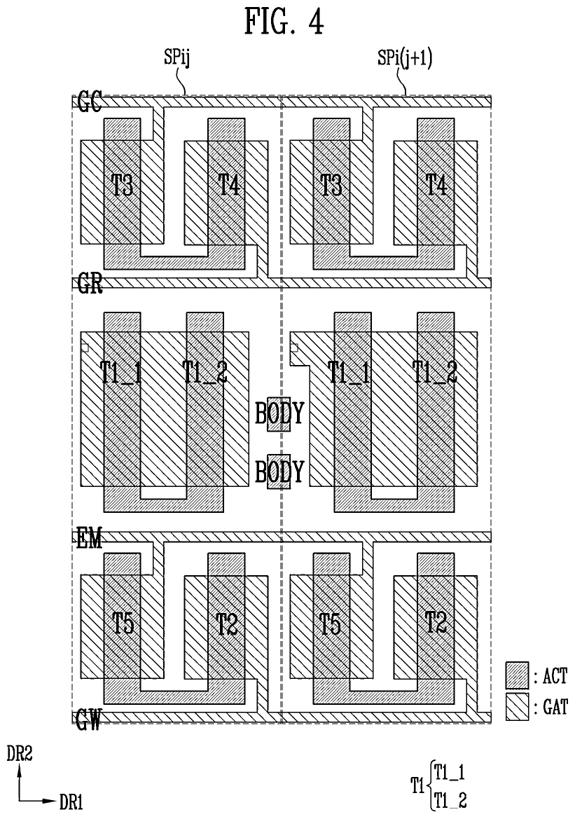

FIG. 4 is a view illustrating a semiconductor layer ACT and a gate electrode layer GAT of sub-pixels SPij and SPi(j+1) in accordance with embodiments of the present disclosure.

In some embodiments, a semiconductor layer ACT may be a portion of a substrate SUB (see FIG. 1). In some embodiments, the active layer ACT may be formed on the substrate SUB separately from the substrate SUB. For example, in an embodiment in which the substrate SUB in accordance with the embodiments of the present disclosure is a silicon substrate, the active layer ACT may be a portion of the substrate SUB.

A gate electrode layer GAT may include a low-resistance metal material. The gate electrode layer GAT may be formed as a single layer or a multi-layer which is made of any one of molybdenum (Mo), aluminum (Al), chromium (Cr), gold (Au), titanium (Ti), nickel (Ni), neodymium (Nd), and copper (Cu), or any alloy thereof.

A gate insulating layer (not shown) configured to insulate the semiconductor layer ACT and the gate electrode layer GAT from each other may be interposed between the semiconductor layer ACT and the gate electrode layer GAT. The gate insulating layer may include an inorganic insulating material. For example, the gate insulating layer may include an inorganic insulating material such as silicon oxide (SiO₂), silicon nitride (SiNₓ) (x is a positive number), silicon oxynitride (SiON), aluminum oxide (Al₂O₃), titanium oxide (TiO₂), tantalum oxide (Ta₂O₅), hafnium oxide (HfO₂), and/or zinc oxide (ZnO₂).

Referring to FIG. 4, a first sub-pixel SPij and a second sub-pixel SPi(j+1), which are adjacent to each other in the first direction DR1, are illustrated.

Each of the first and second sub-pixels SPij and SPi(j+1) may include first to fifth transistors T1 to T5. The first to fifth transistors T1 to T5 may correspond to the first to fifth transistors T1 to T5 of the sub-pixel circuit SPC described above with reference to FIG. 3. Each of the first to fifth transistors T1 to T5 may include a semiconductor layer ACT and a gate electrode layer GAT.

The gate electrode layer GAT may constitute a gate electrode of each of the first to fifth transistors T1 to T5.

The semiconductor layer ACT may constitute a semiconductor layer of each of the first to fifth transistors T1 to T5. The semiconductor layer ACT may include a channel region located in a region in which the semiconductor layer ACT overlaps (e.g., overlaps in a vertical direction) with the gate electrode layer GAT. The semiconductor layer ACT may include a drain region and a source region which are located adjacent to the channel region. The drain region of the semiconductor layer ACT may be connected to a drain electrode of a corresponding transistor. The source region of the semiconductor layer ACT may be connected to a source region of the corresponding transistor.

A semiconductor layer ACT of the third transistor T3 and a semiconductor layer ACT of the fourth transistor T4 may be connected to each other (e.g., integrally formed).

The first transistor T1 may include a (1_1)th transistor T1_1 and a (1_2)th transistor T1_2. The (1_1)th transistor T1_1 and the (1_2)th transistor T1_2 may share a semiconductor layer ACT and a gate electrode layer GAT with each other. Accordingly, the first transistor T1 has the same effect as the length of a channel region is lengthened in the semiconductor layer ACT. However, embodiments of the present disclosure are not limited as described above, and the first transistor T1 may include one transistor.

Gate electrode layers GAT may be connected to each other in the first and second sub-pixels SPij and SPi(j+1) disposed adjacent to each other in the first direction DR1. Referring to FIG. 4, gate electrodes of the second to fifth transistors T2 to T5 disposed adjacent to each other in the first direction DRI may be connected to each other as gate electrode layers GAT.

A body electrode BODY of the first transistor T1 may be located between two sub-pixels disposed adjacent to each other. Accordingly, a space can be efficiently configured. The body electrode BODY may include a semiconductor layer ACT.

At least a portion of the gate electrode layer GAT (e.g., the gate electrode layer GAT constituting the first transistor T1) located at one side of the body electrode BODY (e.g., in the first direction DR1 from the body electrode BOCY) may protrude toward the body electrode BODY. However, embodiments of the present disclosure are not limited thereto. For example, the gate electrode GAT constituting the first transistor T1 may have a quadrangular shape without any portion protruding toward the body electrode BODY.

A first scan signal GW may be input to the gate electrode layer GAT of the second transistor T2. A third scan signal GC may be input to a gate electrode layer GAT of the third transistor T3. A second scan signal GR may be input to a gate electrode layer GAT of the fourth transistor T4. An emission control signal EM may be input to a gate electrode layer GAT of the fifth transistor T5.

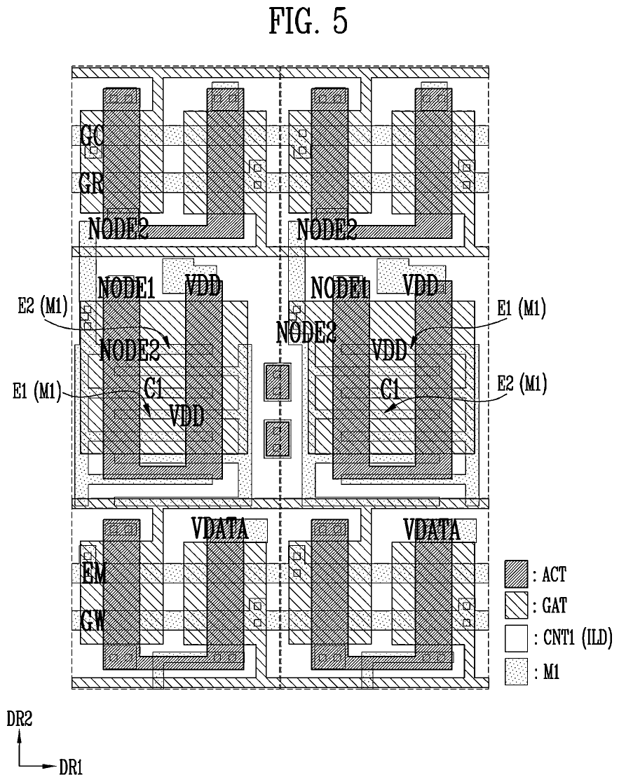

FIG. 5 is a view illustrating the semiconductor layer ACT, the gate electrode layer GAT, a first contact portion CNT1, and a first metal layer M1 of the sub-pixel in accordance with embodiments of the present disclosure.

An interlayer insulating layer ILD may be formed on the gate electrode layer GAT. A first metal layer M1 may be formed on the interlayer insulating layer ILD. In an area in which at least a portion of the interlayer insulating layer ILD is removed, the first metal layer M1 may be connected to (e.g., in contact with) the gate electrode layer GAT or the semiconductor layer ACT. Referring to FIG. 5, at a first contact portion CNT1 included in the interlayer insulating layer ILD, the gate electrode layer GAT and the first metal layer M1 may be connected to each other. Referring to FIG. 5, at the first contact portion CNT1 included in the interlayer insulating layer ILD, the semiconductor layer ACT and the first metal layer M1 may be connected to each other.

The interlayer insulating layer ILD may be formed of an inorganic layer. For

example, the interlayer insulating layer ILD may be formed of a silicon nitride layer, a silicon oxynitride layer, a silicon oxide layer, a titanium oxide layer, or an aluminum oxide layer, but embodiments of the present disclosure are not limited thereto.

The first metal layer M1 may be formed as a single layer or a multi-layer which is made of any one of molybdenum (Mo), aluminum (Al), chromium (Cr), gold (Au), titanium (Ti), nickel (Ni), neodymium (Nd), and copper (Cu), or any alloy thereof, but embodiments of the present disclosure are not limited thereto.

The first metal layer M1 may constitute signal lines entirely extending in the first direction DR1. For example, referring to FIG. 5, the first metal layer M1 may constitute the gate line GLi (see FIG. 2) and the emission control line ELi (see FIG. 2). Referring to FIG. 5, the first metal layer M1 may constitute the first sub-gate line SGL1 (see FIG. 3) to which the first scan signal GW is input, the second sub-gate line SGL2 (see FIG. 3) to which the second scan signal GR is input, and the third sub-gate line SGL3 (see FIG. 3) to which the third scan signal GC is input. The first metal layer M1 may constitute an emission control line EL (see FIG. 3) to which an emission control signal EM is input. The first metal layer M1 constituting the first to third sub-gate lines SGL1 to SGL3 and the emission control line EL may extend in the first direction DR1.

The first metal layer M1 may constitute a second node NODE2. The first metal layer M1 may be connected to the semiconductor layer ACT of the third transistor T3 (see FIG. 4) and the fourth transistor T4 (see FIG. 4). The first metal layer M1 may be connected to the gate electrode layer GAT of the first transistor T1 (see FIG. 4). For example, the first metal layer M1 may be connected to the drain region formed in the semiconductor layer ACT of the third transistor T3 and the fourth transistor T4.

The first power voltage VDD may be applied to the first metal layer M1. The first power voltage VDD may be applied to the source region in the active layer ACT of the first transistor T1 (see FIG. 4) through the metal layer M1. The first power voltage VDD may be applied to a first electrode E1 of a first capacitor C1 through the metal layer M1.

The first metal layer M1 may constitute the first capacitor C1 in an area in which the first metal layer MI overlaps (e.g., overlaps in the vertical direction) with the semiconductor layer ACT and/or the gate electrode layer GAT of the first transistor T1 (see FIG. 4). Referring to FIG. 5, the second node NODE2 may constitute a second electrode E2 (see FIG. 3) of the first capacitor C1 in the area in which the first metal layer M1 overlaps (e.g., overlaps in the vertical direction) with the semiconductor layer ACT and/or the gate electrode layer GAT of the first transistor T1. In order to increase the storage capacitance of the first capacitor C1, the first metal layer M1 constituting the first capacitor C1 may have a branch structure in which the first metal layer M1 constituting each electrode extends along the first direction. The metal layers M1 constituting the first electrode E1 of the first capacitor C1 may be interdigitated with the second electrode E2 of the first capacitor C1 along the second direction DR2. Referring to FIG. 5, the first metal layer M1 may extend along the first direction DR1 in an area in which the first metal layer M1 overlaps with the gate electrode layer GAT of the first transistor T1 in the vertical direction.

The first metal layer M1 may transfer a data signal VDATA. The first metal layer M1 in which the data signal VDATA is written may be connected to the semiconductor layer ACT of the second transistor T2 (see FIG. 4). A region in which the data signal VDATA is written in the semiconductor layer ACT of the second transistor T2 may be a drain region.

The first metal layer M1 may constitute a first node NODE1. Referring to FIG. 5, the metal layer M1 connected to the drain region in the semiconductor layer ACT of the first transistor T1 (see FIG. 4) through the first contact portion CNT1 may constitute the first node NODE1.

The first metal layer M1 may constitute the first capacitor C1. The first electrode E1 of the first capacitor C1 may correspond to an area in which the first power voltage VDD is applied to the first metal layer M1. The second electrode E2 of the first capacitor C1 may correspond to the second node NODE2 in the first metal layer M1.

The first metal layer M1 may constitute the body electrode (see FIG. 4). The first metal layer M1 may be connected to the semiconductor layer ACT constituting the body electrode BODY through the first contact portion CNT1 on the semiconductor layer ACT.

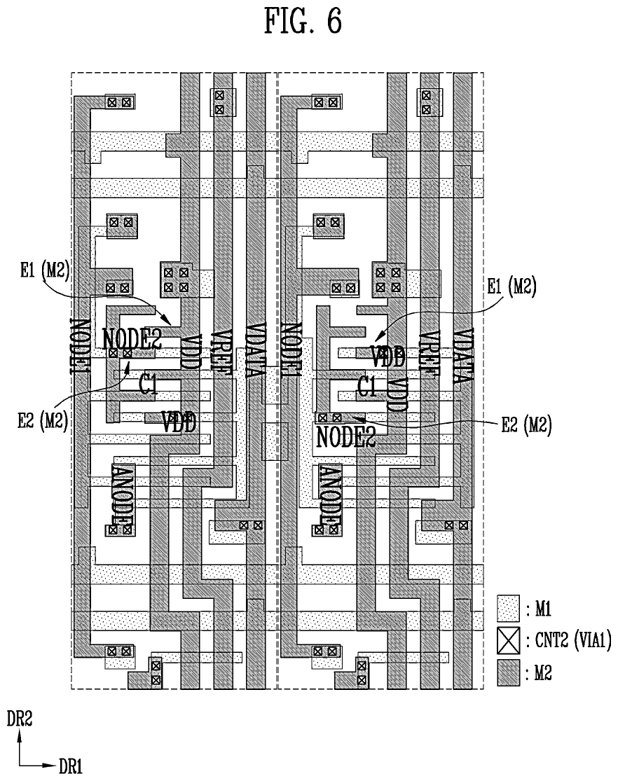

FIG. 6 is a view illustrating the first metal layer M1, a second contact portion CNT2, and a second metal layer M2 of the sub-pixel in accordance with embodiments of the present disclosure.

Referring to FIG. 6, a first via layer VIA1 may be interposed between the first metal layer M1 and a second metal layer M2. The first via layer VIA1 may include a second contact portion CNT2 located in an area in which at least a portion of the first via layer VIA1 is removed. The second metal layer M2 may be connected to (e.g., in contact with) the first metal layer M1 at the second contact portion CNT2.

The first via layer VIA1 may be formed of an organic layer such as acrylic resin, epoxy resin, phenolic resin, polyamide resin, or polyimide resin, but embodiments of the present disclosure are not limited thereto. In some embodiments, the first via layer VIA1 may be formed of an inorganic layer such as a silicon nitride layer, a silicon oxynitride layer, a silicon oxide layer, a titanium oxide layer, or an aluminum oxide layer.

The second metal layer M2 may be formed as a single layer or a multi-layer which is made of any one of molybdenum (Mo), aluminum (Al), chromium (Cr), gold (Au), titanium (Ti), nickel (Ni), neodymium (Nd), and copper (Cu), or any alloy thereof, but embodiments of the present disclosure are not limited thereto.

The second metal layer M2 may constitute the first node NODE1. The second metal layer M2 may be connected to the first metal layer M1 through the second contact portion CNT2. Further referring to FIGS. 4 and 5, the first metal layer M1 may be connected to the source region of the semiconductor layer ACT of the third transistor T3. The first metal layer M1 may be connected to the drain region of the semiconductor layer ACT of the first transistor T1. The first metal layer M1 may be connected to the source region of the semiconductor layer ACT of the fifth transistor T5.

The second metal layer M2 may constitute signal lines entirely extending in the second direction DR2. For example, referring to FIG. 6, the second metal layer M2 may constitute a power line and a data line which entirely extend in the second direction DR2. The second metal layer M2 may constitute the first power line PL1 (see FIG. 3) to which the first power voltage VDD is applied. The second metal layer M2 may constitute the third power line PL3 (see FIG. 3) to which the third power voltage VREF is applied. The second metal layer M2 may constitute a data line DL (see FIG. 3) to which a data signal VDATA is applied.

The second metal layer M2 may apply the first power voltage VDD to the first metal layer M1 at the second contact portion CNT2. Referring to FIGS. 4 and 5, the first metal layer M1 may transfer first power voltage VDD to the source region of the semiconductor layer ACT of the first transistor T1 at the first contact portion CNT1. The first metal layer M1 to which the first power voltage VDD is applied may constitute the first electrode E1 of the first capacitor C1.

The second metal layer M2 may apply the third power voltage VREF to the first metal layer M1 at the second contact portion CNT2. Referring to FIGS. 4 and 5, the source region in the semiconductor layer ACT of the fourth transistor T4 may be connected to the first metal layer M1 such that the third power voltage VREF is applied thereto.

The second metal layer M2 may apply the data signal VDATA to the first metal layer M1 at the second contact portion CNT2. Referring to FIGS. 4 and 5, the drain region in the semiconductor layer ACT of the second transistor T2 may be connected to the first metal layer M1 such that the data signal VDATA is applied thereto.

The second metal layer M2 may constitute at least a portion of an anode ANODE. Further referring to FIG. 3, the second metal layer M2 may constitute at least a portion of an anode electrode AE of a light emitting element LD.

The second metal layer M2 may constitute the first capacitor C1. The first electrode E1 of the first capacitor C1 may correspond to an area in which the first power voltage VDD is applied to the second metal layer M2. The second electrode E2 of the first capacitor C1 may correspond to an area in which the second metal layer M2 is connected to the second node NODE2. At least a portion of the second metal layer M2 constituting the first capacitor C1 may be located while overlapping (e.g., overlapping in the vertical direction) with the first metal layer M1 constituting the first capacitor C1.

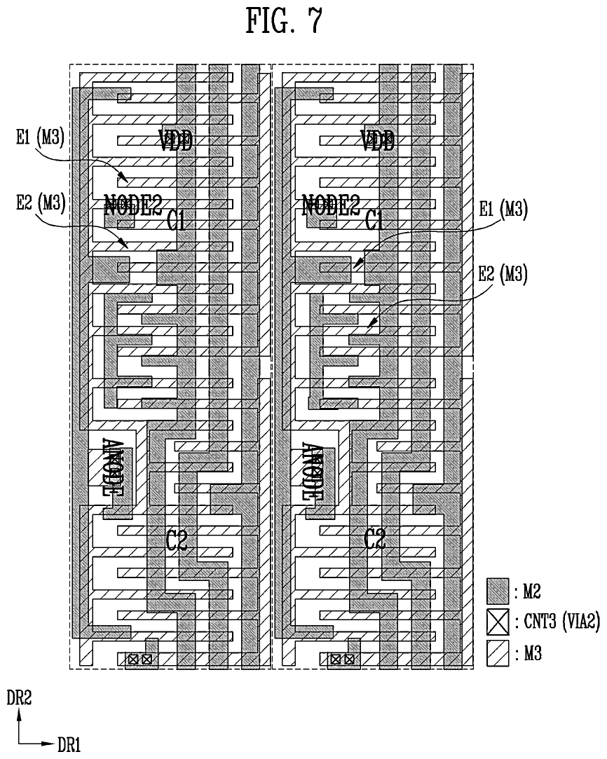

FIG. 7 is a view illustrating the second metal layer M2, a third contact portion CNT3, and a third metal layer M3 of the sub-pixel in accordance with embodiments of the present disclosure.

Referring to FIG. 7, a second via layer VIA2 may be interposed between the second metal layer M2 and a third metal layer M3. The second via layer VIA2 may include a third contact portion CNT3 located in an area in which at least a portion of the second via layer VIA2 is removed. The third metal layer M3 may be connected to (e.g., in contact with) the second metal layer M2 at the third contact portion CNT3.

The second via layer VIA2 may be formed of an organic layer such as acrylic resin, epoxy resin, phenolic resin, polyamide resin, or polyimide resin, but embodiments of the present disclosure are not limited thereto. The second via layer VIA2 may be formed of an inorganic layer such as a silicon nitride layer, a silicon oxynitride layer, a silicon oxide layer, a titanium oxide layer, or an aluminum oxide layer.

The third metal layer M3 may be formed as a single layer or a multi-layer which is made of any one of molybdenum (Mo), aluminum (Al), chromium (Cr), gold (Au), titanium (Ti), nickel (Ni), neodymium (Nd), and copper (Cu), or any alloy thereof, but embodiments of the present disclosure are not limited thereto.

The third metal layer M3 may be connected to the second metal layer M2 at the third contact portion CNT3 such that the first power voltage VDD is applied thereto. The third metal layer M3 may be connected to the second metal layer M2 at the third contact portion CNT3 to constitute the second node NODE2. The third metal layer M3 may be connected to the second metal layer M2 at the third contact portion CNT3 to constitute at least a portion of an anode ANODE.

The third metal layer M3 may constitute the first capacitor C1. The first electrode E1 of the first capacitor C1 may correspond to an area in which the first power voltage VDD is applied to the third metal layer M3. The second electrode E2 of the first capacitor C1 may correspond to an area in which the third metal layer M3 is connected to the second node NODE2. At least a portion of the third metal layer M3 constituting the first capacitor C1 may be connected to the second metal layer M2 to which the first power voltage VDD is applied.

The third metal layer M3 may constitute a second capacitor C2. One electrode of the second capacitor C2 may be connected to the second transistor T2 (see FIG. 4) at a predetermined node T2 NODE. The other electrode of the second capacitor C2 may include the third metal layer M3 connected to the second node NODE2.

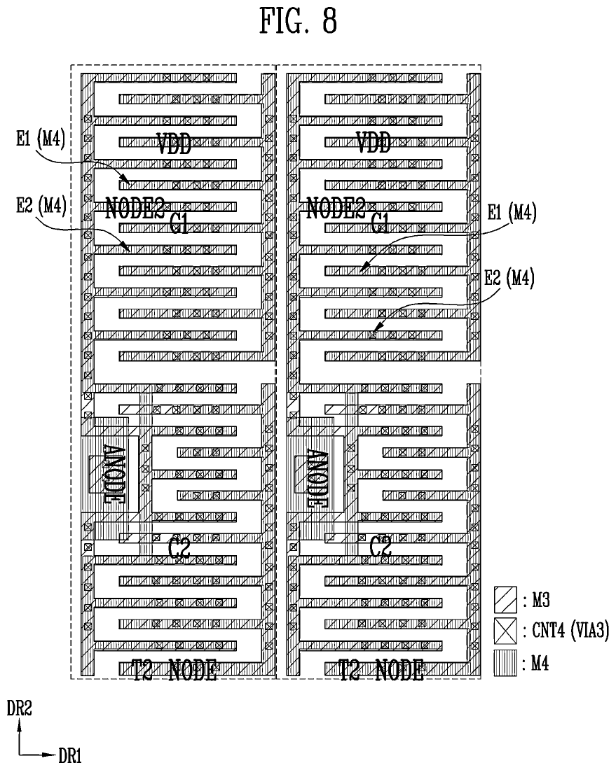

FIG. 8 is a view illustrating a third metal layer M3, a fourth contact portion CNT4, and a fourth metal layer M4 of the sub-pixel in accordance with embodiments of the present disclosure.

Referring to FIG. 8, a third via layer VIA3 may be interposed between a third metal layer M3 and a fourth metal layer M4. The third via layer VIA3 may include a fourth contact portion CNT4 located in an area in which at least a portion of the third via layer VIA3 is removed. The fourth metal layer M4 may be connected to (e.g., in contact with) the third metal layer M3 at the fourth contact portion CNT4.

The third via layer VIA3 may be formed of an organic layer such as acrylic resin, epoxy resin, phenolic resin, polyamide resin, or polyimide resin, but embodiments of the present disclosure are not limited thereto. The third via layer VIA3 may be formed of an inorganic layer such as a silicon nitride layer, a silicon oxynitride layer, a silicon oxide layer, a titanium oxide layer, or an aluminum oxide layer.

The fourth metal layer M4 may be formed as a single layer or a multi-layer which is made of any one of molybdenum (Mo), aluminum (Al), chromium (Cr), gold (Au), titanium (Ti), nickel (Ni), neodymium (Nd), and copper (Cu), or any alloy thereof, but embodiments of the present disclosure are not limited thereto.

The fourth metal layer M4 may be connected to the third metal layer M3 at the fourth contact portion CNT4 such that the first power voltage VDD is applied thereto. The fourth metal layer M4 may be connected to the third metal layer M3 at the fourth contact portion CNT4 to constitute the second node NODE2. The fourth metal layer M4 may be connected to the third metal layer M3 at the fourth contact portion CNT4 to constitute at least a portion of an anode ANODE.

The fourth metal layer M4 may constitute a first capacitor C1. A first electrode E1 of the first capacitor C1 may correspond to an area in which the first power voltage VDD is applied to the fourth metal layer M4. A second electrode E2 of the first capacitor C1 may correspond to an area in which the fourth metal layer M4 is connected to the second node NODE2.

The fourth metal layer M4 may constitute a second capacitor C2. One electrode of the second capacitor C2 may be connected to the second transistor T2 (see FIG. 4) at a predetermined node T2 NODE. The other electrode of the second capacitor C2 may include the fourth metal layer M4 connected to the second node NODE2.

Totally referring to FIGS. 4 to 8, in the sub-pixel SP in accordance with the embodiments of the present disclosure, the first capacitor C1 may include first to fourth metal layers M1 to M4. Accordingly, the capacitance of the first capacitor C1 can be increased.

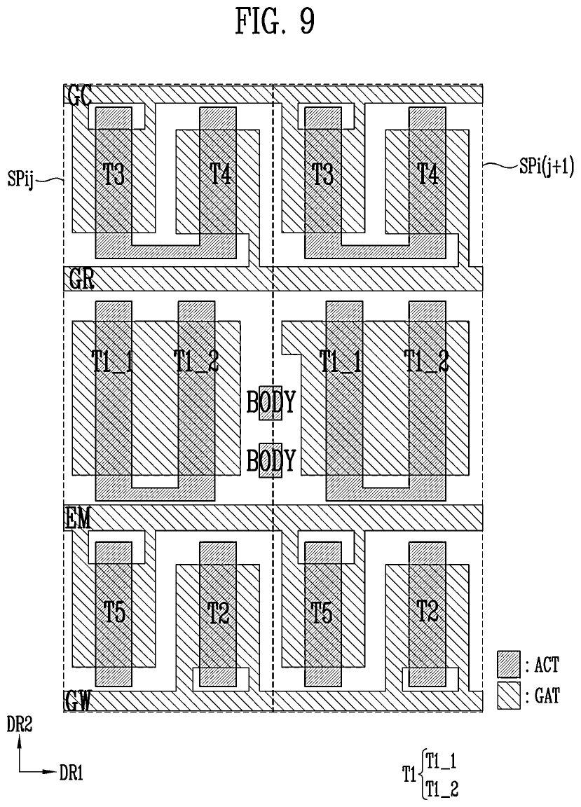

FIG. 9 is a view illustrating a semiconductor layer ACT and a gate electrode layer GAT of a sub-pixel in accordance with other embodiments of the present disclosure.

In some embodiments, a semiconductor layer ACT may be a portion of a substrate SUB (see FIG. 1). In some embodiments, the active layer ACT may be formed on the substrate SUB separately from the substrate SUB. For example, in an embodiment in which the substrate SUB in accordance with the embodiments of the present disclosure is a silicon substrate, the active layer ACT may be a portion of the substrate SUB.

A gate insulating layer (not shown) configured to insulate the semiconductor layer ACT and a gate electrode layer GAT from each other may be interposed between the semiconductor layer ACT and the gate electrode layer GAT.

Referring to FIG. 9, a first sub-pixel SPij and a second sub-pixel SPi(j+1), which are disposed adjacent to each other in the first direction DR1, are illustrated.

Each of the first and second sub-pixels SPij and SPi(j+1) may include first to fifth transistors T1 to T5. The first to fifth transistors T1 to T5 may correspond to the first to fifth transistors T1 to T5 of the sub-pixel circuit SPC described above with reference to FIG. 3. Each of the first to fifth transistors T1 to T5 may include a semiconductor layer ACT and a gate electrode layer GAT.

The gate electrode layer GAT may constitute a gate electrode of each of the first to fifth transistors T1 to T5.

The gate electrode layer GAT may constitute the first sub-gate line SGL1 (see FIG. 3) to which the first scan signal GW is supplied. The gate electrode layer GAT may constitute the second sub-gate line SGL2 (see FIG. 3) to which the second scan signal GR is supplied. The gate electrode layer GAT may constitute the third sub-gate line SGL3 (see FIG. 3) to which the third scan signal GC is supplied. The gate electrode layer GAT may constitute the emission control line EL (see FIG. 3) to which the emission control signal EM is supplied.

The gate electrode layer GAT may be directly connected to the gate driving circuit 120 (see FIG. 1).

The semiconductor layer ACT may constitute a semiconductor layer of each of the first to fifth transistors T1 to T5. The semiconductor layer ACT may include a channel region located in a region in which the semiconductor layer ACT overlaps (e.g., overlaps in a vertical direction) with the gate electrode layer GAT. The semiconductor layer ACT may include a drain region and a source region which are located adjacent to the channel region.

A semiconductor layer ACT of the third transistor T3 and a semiconductor layer ACT of the fourth transistor T4 may be connected to each other (e.g., integrally formed).

The first transistor T1 may include a (1_1)th transistor T1_1 and a (1_2)th transistor T1_2. The (1_1)th transistor T1_1 and the (1_2)th transistor T1_2 may share a semiconductor layer ACT and a gate electrode layer GAT with each other. Accordingly, the first transistor T1 has the same effect as the length of a channel region is lengthened in the semiconductor layer ACT. However, embodiments of the present disclosure are not limited to that described above, and the first transistor T1 may include one transistor.

Gate electrode layers GAT may be connected to each other in the first and second sub-pixels SPij and SPi(j+1) disposed adjacent to each other in the first direction DR1. Referring to FIG. 9, gate electrodes of the second to fifth transistors T2 to T5 adjacent to each other in the first direction DR1 may be connected to each other as gate electrode layers GAT.

A body electrode BODY of the first transistor T1 may be located between two sub-pixels adjacent to each other. The body electrode BODY may include a semiconductor layer ACT.

At least a portion of the gate electrode layer GAT (e.g., the gate electrode layer GAT constituting the first transistor T1) located at one side of the body electrode BODY (e.g., in the first direction DR1 from the body electrode BOCY) may protrude toward the body electrode BODY. However, embodiments of the present disclosure are not limited thereto. For example, the gate electrode GAT constituting the first transistor T1 may have a quadrangular shape without any portion protruding toward the body electrode BODY.

A first scan signal GW may be input to the gate electrode layer GAT of the second transistor T2. A third scan signal GC may be input to a gate electrode layer GAT of the third transistor T3. A second scan signal GR may be input to a gate electrode layer GAT of the fourth transistor T4. An emission control signal EM may be input to a gate electrode layer GAT of the fifth transistor T5.

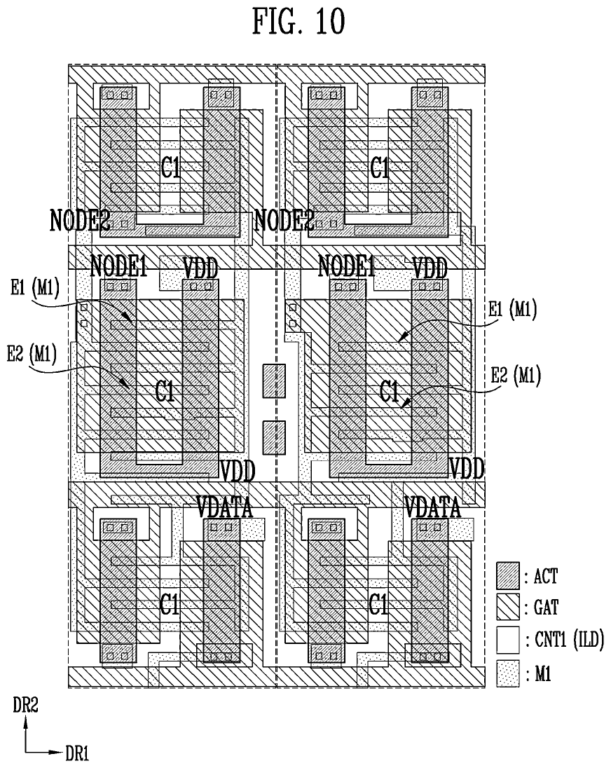

FIG. 10 is a view illustrating the semiconductor layer ACT, the gate electrode layer GAT, a first contact portion CNT1, and a first metal layer M1 of a sub-pixel in accordance with other embodiments of the present disclosure.

An interlayer insulating layer ILD may be formed on the gate electrode layer GAT. A first metal layer M1 may be formed on the interlayer insulating layer ILD. In an area in which at least a portion of the interlayer insulating layer ILD is removed, the first metal layer M1 may be connected to (e.g., in contact with) the gate electrode layer GAT or the semiconductor layer ACT. Referring to FIG. 10, at a first contact portion CNT1, the gate electrode layer GAT and the first metal layer M1 may be connected to each other. Alternatively, at the first contact portion CNT1 included in the interlayer insulating layer ILD, the semiconductor layer ACT and the first metal layer M1 may be connected to each other.

The first metal layer M1 may constitute a second node NODE2. The first metal layer M1 may be connected to the semiconductor layer ACT of the third transistor T3 (see FIG. 9) and the fourth transistor T4 (see FIG. 9). The first metal layer M1 may be connected to the gate electrode layer GAT of the first transistor T1 (see FIG. 9). For example, the first metal layer M1 may be connected to the drain region formed in the semiconductor layer ACT of the third transistor T3 and the fourth transistor T4.

The first power voltage VDD may be applied to the first metal layer M1. The first power voltage VDD may be applied to the source region in the active layer ACT of the first transistor T1 (see FIG. 9) through the metal layer M1. The first power voltage VDD may be applied to a first electrode E1 of a first capacitor C1 through the metal layer M1.

As compared with FIG. 5, referring to FIG. 10, the first to third scan signals GW, GR, and GC and the emission control signal EM may not be input through the first metal layer M1. Referring to FIG. 10 together with FIG. 9, the first capacitor C1 may be formed in an area overlapping with the gate electrode layer GAT of the first to fifth transistors T1 to T5. The first metal layer M1 constituting the second node NODE2 may be located while overlapping with the gate electrode layer GAT of the first to fifth transistors T1 to T5. The first metal layer M1 to which the first power voltage VDD is applied may be located while overlapping with the gate electrode layer GAT of the first to fifth transistors T1 to T5.

In order to increase the storage capacitance of the first capacitor C1, the first metal layer M1 constituting the first capacitor C1 may have a branch structure in which the first metal layer M1 constituting each electrode extends along the first direction. The metal layers M1 constituting the first electrode E1 of the first capacitor C1 may be interdigitated with the second electrode E2 of the first capacitor C1 along the second direction DR2.

The first metal layer M1 may transfer a data signal VDATA. The data signal VDATA may be input to the drain region in the semiconductor layer ACT of the second transistor T2 (see FIG. 9).

The first metal layer M1 may constitute a first node NODE1. Referring to FIG. 9, the first metal layer M1 connected to the drain region in the semiconductor layer ACT of the first transistor T1 through the first contact portion CNT1 may constitute the first node NODE1.

The first metal layer M1 may constitute the body electrode BODY (see FIG. 9). The metal layer M1 may be connected to the semiconductor layer ACT constituting the body electrode BODY through the first contact portion CNT1 on the semiconductor layer ACT.

Second to fourth metal layers may be further formed on the first metal layer M1. The second to fourth metal layers may be formed identically or similarly to the second to fourth metal layers M2 to M4 described above with reference to FIGS. 6 to 8.

Referring to FIGS. 9 and 10, the capacitance of the first capacitor C1 in accordance with the embodiments of the present disclosure can be further increased.

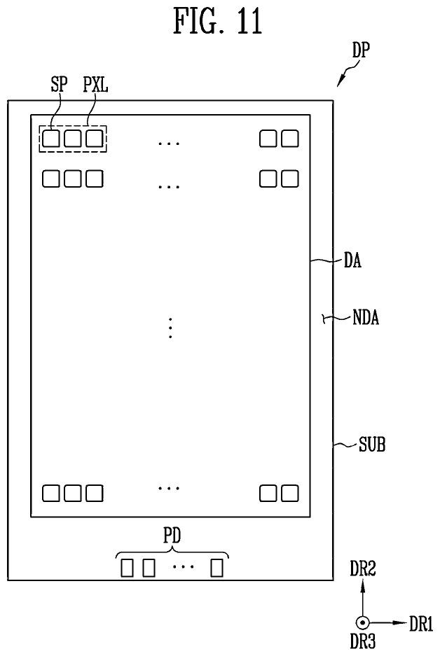

FIG. 11 is a plan view illustrating an embodiment of the display panel 110 shown in FIG. 1.

A display panel DP shown in FIG. 11 may be applied to the display panel 110 shown in FIG. 1.

Referring to FIG. 11, the display panel DP may include a display area DA and a non-display area NDA. The display panel DP may display an image through the display area DA. The non-display area NDA may be disposed at the periphery (e.g., in an edge area) of the display area DA.

The display panel DP may include a substrate SUB, a plurality of sub-pixels SP disposed (or formed) on the substrate SUB, and a plurality of pads PD disposed (or formed) on the substrate SUB.

When the display panel DP in accordance with the embodiments of the present disclosure is used as a display screen of a Head Mounted Display (HMD), a Virtual Reality (VR) device, a Mixed Reality (MR) device, an Augmented Reality (AR) device, and the like, the display panel DP may be located very close to eyes of a user. In the above embodiment, it may be required for the sub-pixels SP to be integrated with a relatively high density. In order to increase the integration of the sub-pixels SP, the substrate SUB in accordance with the embodiments of the present disclosure may be provided as a silicon substrate. The sub-pixels SP and/or the display panel DP may be formed on the substrate SUB as the silicon substrate. The display device 100 (see FIG. 1) including the display panel DP formed on the substrate SUB as the silicon substrate may be designated as an OLED on Silicon (OLEDoS) display device.

The plurality of sub-pixels SP may be disposed in the display area DA on the substrate SUB. Referring to FIG. 11, the sub-pixels SP may be arranged in a matrix form along the first direction DR1 and the second direction DR2 intersecting the first direction DR1. However, embodiments of the present disclosure are not limited thereto. For example, the plurality of sub-pixels SP in accordance with the embodiments of the present disclosure may be arranged in a zigzag form along the first direction DR1 and the second direction DR2. For example, the plurality of sub-pixels SP may be disposed in a PENTILE™ form. The first direction DRI may be a row direction, and the second direction DR2 may be a column direction. Two or more sub-pixels among the plurality of sub-pixels SP may constitute one pixel PXL.

A component for controlling the sub-pixels SP may be disposed in the non-display area NDA on the substrate SUB. For example, signal lines such as the first to mth gate lines GL1 to GLm and the first to nth data lines DL1 to DLn, which are shown in FIG. 1, may be disposed to extend to at least a portion of the non-display area NDA.

At least one of the gate driving circuit 120, the data driver 130, the voltage generator 140, the controller 150, and the temperature sensor 160, which are shown in FIG. 1, may be disposed (e.g., disposed to be integrated) in the non-display area NDA of the display panel DP.

In an embodiment, the gate driving circuit 120 shown in FIG. 1 may be formed and disposed in the non-display area NDA of the display panel DP. In another embodiment, the gate driving circuit 120 may be implemented as a separate integrated circuit and mounted in the non-display area NDA.

In an embodiment, the temperature sensor 160 shown in FIG. 1 may be disposed in the non-display area NDA to sense a temperature of the display panel DP. The temperature sensor 160 may be disposed at a vertex or in an area corresponding thereto. Two or more temperature sensors160 may be disposed in the display panel DP.

The pads PD may be disposed in the non-display area NDA on the substrate SUB. The pads PD may be electrically connected to the sub-pixels SP through the signal lines. For example, the pads PD may be connected to the sub-pixels SP through the first to nth data lines DL1 to DLn.

The display panel DP may be connected to other components of the display device 100 (see FIG. 1) through the pads PD. In embodiments, voltages and signals, which are necessary for operations of components included in the display panel DP, may be provided from the driver integrated circuit DIC shown in FIG. 1 through the pads PD. For example, the first to nth data lines DL1 to DLn (see FIG. 1) may be connected to the driver integrated circuit DIC through the pads PD. For example, the first and second power voltages VDD and VSS (see FIG. 1) may be received from the driver integrated circuit DIC through the pads PD. In an embodiment in which the gate driving circuit 120 (see FIG. 1) is mounted in the display panel DP, the gate control signal GCS may be transmitted from the driver integrated circuit DIC to the gate driving circuit 120 through the pads PD.

In embodiments, a circuit board may be electrically connected to the pads PD using a conductive adhesive member such as an anisotropic conductive film. The circuit board may be a Flexible Printed Circuit Board (FPCB) or a flexible film, which has a flexible material. The driver integrated circuit DIC (see FIG. 1) may be mounted on the circuit board to be electrically connected to the pads PD.

In embodiments, the display area DA may have various shapes. For example, the display area DA may have a closed-loop shape including linear sides and/or curved sides. For example, the display area DA may have shapes such as a polygon, a circle, a semicircle, and an ellipse.

In embodiments, the display panel DP may have a flat display surface. In other embodiments, the display panel DP may at least partially have a rounded display surface. In embodiments, the display panel DP may be bendable, foldable or rollable. The display panel DP and/or the substrate SUB may include rigid or flexible materials.

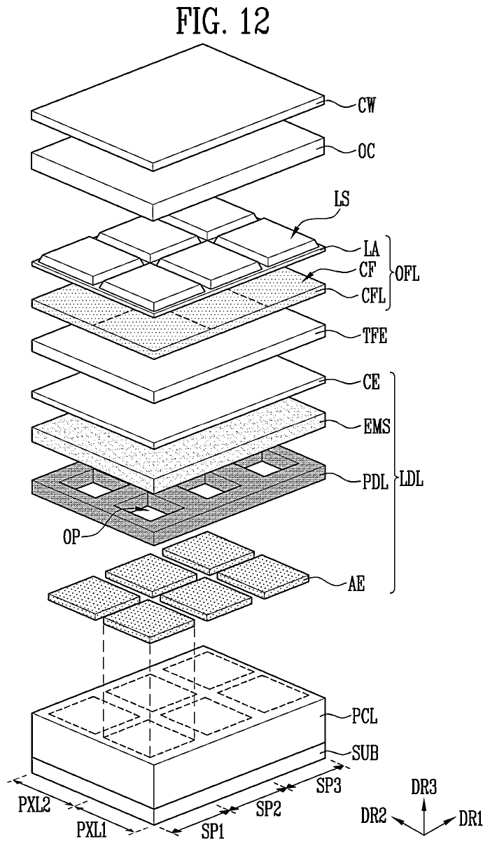

FIG. 12 is an exploded perspective view illustrating a portion of the display panel DP shown in FIG. 11.

In FIG. 12, for clear and brief description, a portion of the display panel DP, which corresponds to first and second pixels PXL1 and PXL2 among the pixels PXL shown in FIG. 11, is schematically illustrated. A portion of the display panel DP, which corresponds to the other pixels, may also have an identical structure to the first and second pixels PXL1 and PXL2.

Referring to FIGS. 11 and 12, the first and second pixels PXL1 and PXL2 may be disposed adjacent to each other in the second direction DR2. Each of the first and second pixels PXL1 and PXL2 may include a plurality of sub-pixels. Referring to FIG. 12, each of the first and second pixels PXL1 and PXL2 may include first, second, and third sub-pixels SP1, SP2, and SP3. However, embodiments of the present disclosure are not limited thereto. For example, each of the first and second pixels PXL1 and PXL2 may include four sub-pixels or include two sub-pixels.

In FIG. 12, it is illustrated that the first to third sub-pixels SP1 to SP3 may have quadrangular shapes when viewed in a third direction DR3 intersecting the first and second directions DR1 and DR2 (e.g., perpendicular to the first and second directions DR1 and DR2), and have the same size. However, embodiments of the present disclosure are not limited thereto. The first to third sub-pixels SP1 to SP3 may be modified to have various shapes.

The display panel DP may include a substrate SUB, a pixel circuit layer PCL, a light emitting element layer LDL, a thin film encapsulation layer TFE, an optical functional layer OFL, an overcoat layer OC, and a cover window CW.

In embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a Silicon On Insulator (SOI) layer, a Semiconductor On Insulator (SeOI) layer, or the like. In other embodiments, the substrate SUB may include a glass substrate. In still other embodiments, the substrate SUB may include a polyimide (PI) substrate.

The pixel circuit layer PCL may be disposed on the substrate SUB. The substrate SUB and/or the pixel circuit layer PCL may include insulating layers and conductive patterns disposed between the insulating layers. The conductive patterns of the pixel circuit layer PCL may serve as at least some of circuit elements, lines, and the like. The conductive patterns may include copper, but embodiments of the present disclosure are not limited thereto. The pixel circuit layer PCL may include the gate insulating layer (not shown), the interlayer insulating layer ILD, the gate electrode layer GAT, the first to fourth metal layers M1 to M4, and the first to third via layers VIA1 to VIA3, which are described above with reference to FIGS. 4 to 10.

The circuit elements may include a sub-pixel circuit SPC (see FIG. 2) of each of the first to third sub-pixels SP1 to SP3. The sub-pixel circuit SPC may include at least two transistors and at least one capacitor. Each transistor may include a semiconductor portion including a source region, a drain region, and a channel region, and a gate electrode overlapping with the semiconductor portion (e.g., the channel region of the semiconductor portion). In an embodiment in which the substrate SUB is provided as a silicon substrate, the semiconductor portion may be included in the substrate SUB, and the gate electrode may be included as a conductive pattern of the pixel circuit layer PCL in the pixel circuit layer PCL. In an embodiment in which the substrate SUB is provided as a glass substrate or a PI substrate, the semiconductor portion and the gate electrode may be included in the pixel circuit layer PCL. The capacitor may include electrodes spaced apart from each other (e.g., face each other). For example, each capacitor may include electrodes spaced apart from each other in the third direction DR3 with an insulating layer interposed therebetween.

The lines of the pixel circuit layer PCL may include signal lines, e.g., a gate line, an emission control line, a data line, and the like, which are connected to each of the first to third sub-pixels SP1 to SP3. The lines may further include a line connected to the first power voltage node VDDN shown in FIG. 2. The lines may further include a line connected to the second power voltage node VSSN shown in FIG. 2.

The light emitting element layer LDL may include anode electrodes AE, a pixel defining layer PDL, a light emitting structure EMS, and a cathode electrode CE.

The anode electrodes AE may be disposed on the pixel circuit layer PCL. The anode electrodes AE may be connected to (e.g., in contact with) the circuit elements of the pixel circuit layer PCL. The anode electrodes AE may include an opaque conductive material capable of reflecting light. However, embodiments of the present disclosure are not limited thereto. In embodiments, the anode electrode AE may include at least one of transparent conductive materials such as Indium Tin Oxide (ITO), Indium Zinc Oxide (IZO), Zinc Oxide (ZnO), Indium Gallium Zinc Oxide (IGZO), and Indium Tin Zinc Oxide (ITZO). However, the material of the anode electrode AE is not limited thereto. For example, the anode electrode AE may include titanium nitride.

The pixel defining layer PDL may be disposed on the anode electrodes AE. The pixel defining layer PDL may include an opening OP exposing at least a portion of each of the anode electrodes AE. The opening OP of the pixel defining layer PDL may correspond to an emission area of each of the first to third sub-pixels SP1 to SP3.

In embodiments, the pixel defining layer PDL may include an inorganic material. In the above embodiment, the pixel defining layer PDL may include an inorganic layer (e.g., a plurality of stacked inorganic layers). For example, the pixel defining layer PDL may include silicon oxide (SiOₓ) and/or silicon nitride (SiNₓ). In other embodiments, the pixel defining layer PDL may include an organic layer including an organic material. However, the material constituting material of the pixel defining layer PDL in accordance with the embodiments of the present disclosure is not limited as described above.

The light emitting structure EMS may be disposed on the anode electrodes AE exposed by the openings OP of the pixel defining layer PDL. The light emitting structure EMS may include at least one functional layer. The light emitting structure EMS may include, for example, functional layers such as a light generation layer (or light emitting layer) (not shown) configured to generate light, an electron transport layer configured to transport electrons, and a hole transport layer configured to transport holes.

In embodiments, the light emitting structure EMS may at least partially fill the openings OP of the pixel defining layer PDL. In embodiments, the light emitting structure EMS may be entirely disposed on the top of the pixel defining layer PDL. For example, the light emitting structure EMS may extend throughout the first to third sub-pixels SP1 to SP3. In the above embodiment, at least some of the functional layers in the light emitting structure EMS may be cut or bent at boundaries between the first to third sub-pixels SP1 to SP3. However, embodiments of the present disclosure are not limited thereto. For example, portions of the light emitting structure EMS, which correspond to the first to third sub-pixels SP1 to SP3, may be separated from each other, and each of the portions may be disposed in the opening OP of the pixel defining layer PDL.

The cathode electrode CE may be disposed on the light emitting structure EMS. The cathode electrode CE may extend throughout the first to third sub-pixels SP1 to SP3. The cathode electrode CE may be provided as a common electrode commonly connected to the first to third sub-pixels SP1 to SP3.

The cathode electrode CE may have light transmittance. For example, the cathode electrode CE may be a thin metal layer having a thickness to a degree to which light emitted from the light emitting structure EMS can be transmitted therethrough. The cathode electrode CE may be formed of a metal material to have a relatively thin thickness or be formed of a conductive material having light transmittance. In embodiments, the cathode electrode CE may include at least one of various transparent conductive materials including indium tin oxide, indium zinc oxide, indium tin zinc oxide, aluminum zinc oxide, gallium zinc oxide, zinc tin oxide, and gallium tin oxide. However, the material constituting the cathode electrode CE in accordance with the embodiments of the present disclosure is not limited as described above. The cathode electrode CE may serve as a half mirror which allows light emitted from the light emitting structure EMS to be partially transmitted therethrough and allows light emitted from the light emitting structure EMS to be partially reflected therefrom.

It may be understood that any one of the anode electrodes AE, a portion of the light emitting structure EMS, and a portion of the cathode electrode CE overlapping each other constitute one light emitting element LD (see FIG. 2). Each of light emitting elements LD of the first to third sub-pixels SP1 to SP3 may include one anode electrode AE, a portion of the light emitting structure EMS, and a portion of the cathode electrode CE overlapping each other. In each of the first to third sub-pixels SP1 to SP3, holes injected from the anode electrode AE and electrons injected from the cathode electrode CE may be transported into the light emitting structure EMS to form excitons, and light may be generated when the excitons are changed from an excited state to a ground state. A luminance of the light may be determined according to an amount of current flowing through the light emitting structure EMS. A wavelength band of the generated light may be determined according to a configuration of the light emitting structure EMS.

The thin film encapsulation layer TFE may be disposed over the cathode electrode CE. The thin film encapsulation layer TFE may cover the light emitting element layer LDL and/or the pixel circuit layer PCL. The thin film encapsulation layer TFE may prevent oxygen and/or moisture from infiltrating into the light emitting element layer LDL. In embodiments, the thin film encapsulation layer TFE may include a structure in which at least one inorganic layer and at least one organic layer are alternately stacked. For example, the inorganic layer may include silicon nitride, silicon oxide, silicon oxynitride (SiOₓN_{y}), or the like. For example, the organic layer may include an organic insulating material such as acrylic resin, epoxy resin, phenolic resin, polyamide resin, polyimide resin, unsaturated polyester resin, polyphenylene resin, polyphenylenesulfide resin, or benzocyclobutene (BCB). However, the materials of the organic layer and the inorganic layer of the thin film encapsulation layer TFE are not limited as described above.

In order to improve encapsulation efficiency of the thin film encapsulation layer TFE, the thin film encapsulation layer TFE may further include a thin film including aluminum oxide (AlOₓ). The thin film including the aluminum oxide may be located on a top surface of the thin film encapsulation layer TFE which faces the optical functional layer OFL, and/or a bottom surface of the thin film encapsulation layer TFE which faces the light emitting element layer LDL. The thin film including the aluminum oxide may be formed through an Atomic Layer Deposition (ALD) process. However, embodiments of the present disclosure are not limited thereto. The thin film encapsulation layer TFE may further include a thin film formed of at least one of various materials suitable for the improvement of the encapsulation efficiency.

The optical functional layer OFL may be disposed on the thin film encapsulation layer TFE. The optical functional layer OFL may include a color filter layer CFL and a lens array LA. In embodiments, the optical functional layer OFL may be attached to the thin film encapsulation layer TFE through an adhesive layer (not shown). For example, the optical functional layer OLF may be separately manufactured to be attached to the thin film encapsulation layer TFE through the adhesive layer. The adhesive layer may further perform a function of protecting lower layers including the thin film encapsulation layer TFE.

The color filter layer CFL may be disposed between the thin film encapsulation layer TFE and the lens array LA. The color filter layer CFL may include filter light emitted from the light emitting structure EMS, thereby selectively outputting light having a wavelength band corresponding to each sub-pixel. The color filter layer CFL may include color filters CF respectively corresponding to the first to third sub-pixels SP1 to SP3. Each of the color filters CF may allow light having a wavelength band corresponding to a corresponding sub-pixel to pass therethrough. For example, a color filter corresponding to the first sub-pixel SP1 may allow light of a red color to pass therethrough, a color filter corresponding to the second sub-pixel SP2 may allow light of a green color to pass therethrough, and a color filter corresponding to the third sub-pixel SP3 may allow light of a blue color to pass therethrough. According to light emitted from the light emitting structure EMS in each sub-pixel, at least some of the color filters CF may be omitted. In some embodiments, the color filter layer CFL may be omitted. In embodiments, the color filters CF may overlap (e.g., partially overlap) with each other in boundary areas between the first to third sub-pixels SP1 to SP3. In other embodiments, the color filters CF may be spaced apart from each other in the boundary areas between the first to third sub-pixels SP1 to SP3, and a black matrix may be provided between the color filters CF.

The lens array LA may be disposed on the color filter layer CFL. The lens array LA may include lenses LS respectively corresponding to the first to third sub-pixels SP1 to SP3. Each of the lenses LS may output light emitted from the light emitting structure EMS along an intended path, thereby improving light emission efficiency. In embodiments, the lenses LS may include an organic material. In embodiments, the lenses LS may include an acryl-based material. However, the material of the lenses LS is not limited thereto.

In embodiments, at least some of the color filters CF and/or at least some of the lenses LS may be misaligned with the openings OP in the pixel defining layer PDL. For example, at least some of the color filters CF of the color filter layer CFL and at least some of the lenses LS of the lens array LA may be shifted in any one direction parallel to a plane defined by the first and second directions DR1 and DR2.

Specifically, in a central area of the display area DA, the center of the color filter CF and the center of the lens LS may be aligned or overlap with the center of a corresponding opening OP of the pixel defining layer PDL when viewed in the third direction DR3. For example, in the central area of the display area DA, the opening OP of the pixel defining layer PDL may completely overlap with a corresponding color filter CF of the color filter layer CFL and a corresponding lens LS of the lens array LA. In an area adjacent to the non-display area NDA of the display area DA, the center of the color filter CF and the center of the lens LS may be shifted from the center of the opening OP of the pixel defining layer PDL when viewed in the third direction DR3. For example, in an area adjacent to the non-display area NDA of the display area DA, the opening OP of the pixel defining layer PDL may partially overlap with a corresponding color filter CF of the color filter layer CFL and a corresponding lens LS of the lens array LA. Accordingly, at the center of the display area DA, light emitted from the light emitting structure EMS can be efficiently output in a normal direction of the display surface. At an outer portion of the display area DA, light emitted from the light emitting structure EMS can be efficiently output in a direction inclined by a predetermined angle with respect to the normal direction.

The overcoat layer OC may be disposed over the lens array LA. The overcoat layer OC may cover the optical functional layer OFL, the thin film encapsulation layer TFE, the light emitting structure EMS, and/or the pixel circuit layer PCL. The overcoat layer OC may include various materials suitable for protecting layers disposed thereunder from foreign matters such as dust and moisture.

The cover window CW may be disposed on the overcoat layer OC. The cover window CW may protect lower layers disposed thereunder. In some embodiments, the cover window CW may include glass, metal, and the like, which have light transmittance. However, embodiments of the present disclosure are not limited thereto.

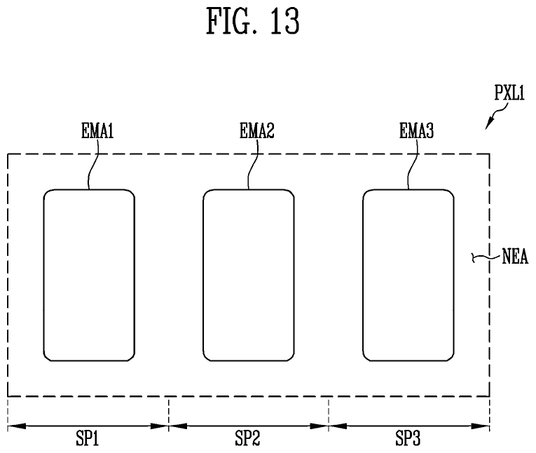

FIG. 13 is a plan view illustrating an embodiment of any one of the pixels shown in FIG. 12.

In FIG. 13, for clear and brief description, the first pixel PXL1 among the first and second pixels PXL1 and PXL2 shown in FIG. 12 is schematically illustrated. The other pixels may have identical structure to the first pixel PXL1. The first pixel PXL1 may include first to third sub-pixels SP1 to SP3 arranged in the first direction DR1.

The first sub-pixel SP1 may include a first emission area EMAl and a non-emission area NEA at the periphery of the first emission area EMA1. The second sub-pixel SP2 may include a second emission area EMA2 and the non-emission area at the periphery of the second emission area EMA2. The third sub-pixel SP3 may include a third emission area EMA3 and the non-emission area at the periphery of the third emission area EMA3.

The first emission area EMA1 may be an area in which light is emitted from the light emitting structure EMS (see FIG. 11) which corresponds to the first sub-pixel SP1. The second emission area EMA2 may be an area in which light is emitted from the light emitting structure EMS which corresponds to the second sub-pixel SP2. The third emission area EMA3 may be an area in which light is emitted from the light emitting structure EMS which corresponds to the third sub-pixel SP3. As described with reference to FIG. 12, each emission area may be understood as an opening OP of the pixel defining layer PDL which corresponds to each of the first to third sub-pixels SP1 to SP3.

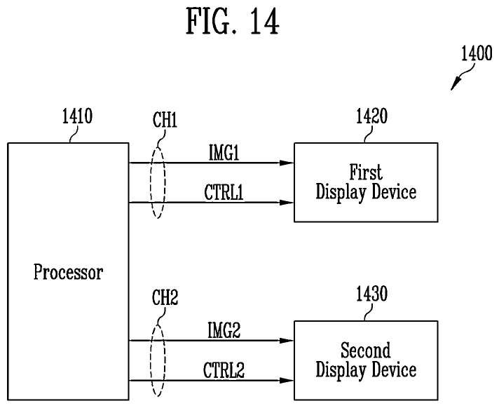

FIG. 14 is a diagram illustrating an embodiment of a display system 1400 in accordance with embodiments of the present disclosure.

Referring to FIG. 14, a display system 1400 may include a processor 1410 and one or more display devices 1420 and 1430.

The processor 1410 may perform various tasks and various calculations. In embodiments, the processor 1410 may include an Application Processor (AP), a Graphics Processing Unit (GPU), a microprocessor, a Central Processing Unit (CPU), and the like. The processor 1410 may be connected to other components of the display system 1400 through a bus to control the components of the display system 1400.

In FIG. 14, it is illustrated that the display system 1400 includes first and second display devices 1420 and 1430. The processor 1410 may be connected to the first display device 1420 through a first channel CH1, and be connected to the second display device 1430 through a second channel CH2.

Through the first channel CH1, the processor 1410 may transmit first image data IMG1 and a first control signal CTRL1 to the first display device 1420. The first display device 1420 may display an image based on the first image data IMG1 and the first control signal CTRL1. The first display device 1420 may be identical to the display device 100 described with reference to FIG. 1. The first image data IMG1 and the first control signal CTRL1 may be respectively provided as the input image data IMG and the control signal CTRL which are shown in FIG. 1.

Through the second channel CH2, the processor 1410 may transmit second image data IMG2 and a second control signal CTRL2 to the second display device 1430. The second display device 1430 may display an image based on the second image data IMG2 and the second control signal CTRL2. The second display device 1430 may be identical to the display device 100 described with reference to FIG. 1. The second image data IMG2 and the second control signal CTRL2 may be respectively provided as the image data IMG and the control signal CTRL which are shown in FIG. 1.

The display system 1400 may include a computing system for providing an image display function such as a portable computer, a mobile phone, a smartphone, a tablet personal computer (PC), a smart watch, a watch phone, a portable multimedia player (PMP), a navigation system, or an ultra mobile computer (UMPC). Also, the display system 1400 may include at least one of a head-mounted display (HMD) device, a virtual reality (VR) device, a mixed reality (MR) device, and an augmented reality (AR) device.

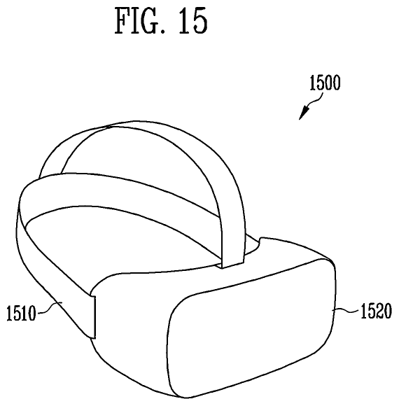

FIG. 15 is a perspective view illustrating an application example of the display system 1400 shown in FIG. 14.

Referring to FIG. 15, the display system 1400 shown in FIG. 14 may be applied to a head-mounted display device 1500. The head-mounted display device 1500 may be a wearable electronic device which can be worn on a head of a user.

The head-mounted display device 1500 may include a head mounting band 1510 and a display device accommodating case 1520. The head mounting band 1510 may be connected to the display device accommodating case 1520. The head mounting band 1510 may include a horizontal band and/or a vertical band used to fix the head-mounted display device 1500 to the head of the user. The horizontal band may be configured to surround a side portion of the head of the user, and the vertical band may be configured to surround an upper portion of the head of the user. However, embodiments of the present disclosure are not limited thereto. For example, the head mounting band 1510 may be implemented in the form of a glasses frame, a helmet or the like.

The display device accommodating case 1520 may accommodate the first and second display devices 1420 and 1430 shown in FIG. 14. The display device accommodating case 1520 may further accommodate the processor 1410 shown in FIG. 14.

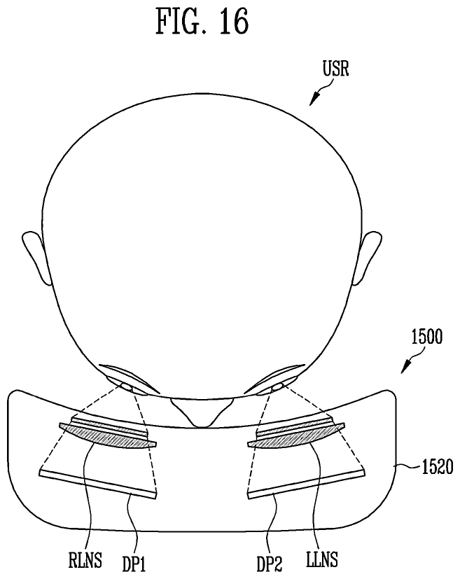

FIG. 16 is a view illustrating the head-mounted display device 1500 worn by a user USR.

Referring to FIG. 16, a first display panel DP1 of the first display device 1420 (see FIG. 14) and a second display panel DP2 of the second display device 1430 (see FIG. 14) may be disposed in the head-mounted display device 1500. The head-mounted display device 1500 may further include one or more lenses. For example, the head-mounted display device 1500 may include a left-eye lens LLNS and a right-eye lens RLNS.

In the display device accommodating case 1520, the right-eye lens RLNS may be disposed between the first display panel DP1 and a right eye of a user USR. In the display device accommodating case 1520, the left-eye lens LLNS may be disposed between the second display panel DP2 and a left eye of the user USR.

An image output from the first display panel DP1 may be viewed by the right eye of the user USR through the right-eye lens RLNS. The right-eye lens RLNS may refract light emitted from the first display panel DP1 to face the right eye of the user USR. The right-eye lens RLNS may perform an optical function for adjusting a viewing distance between the first display panel DP1 and the right eye of the user USR.

An image output from the second display panel DP2 may be viewed by the left eye of the user USR through the left-eye lens LLNS. The left-eye lens LLNS may refract light emitted from the second display panel DP2 to face the left eye of the user USR. The left-eye lens LLNS may perform an optical function for adjusting a viewing distance between the second display panel DP2 and the left eye of the user USR.

In embodiments, each of the right-eye lens RLNS and the left-eye lens LLNS may include an optical lens having a pancake-shaped section. In embodiments, each of the right-eye lens RLNS and the left-eye lens LLNS may include a multi-channel lens including sub-areas having different optical characteristics. In the above embodiment, each of the first and second display panels DP1 and DP2 may output images respectively corresponding to the sub-areas of the multi-channel lens, and the output images may be viewed by the user while respectively passing through corresponding sub-areas.

In the sub-pixel and the display device including the same in accordance with the present disclosure, the capacitance of a capacitor can be increased.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A sub-pixel comprising:
a light emitting element;
a first transistor connected between a first power line and a first node, the first transistor including a gate electrode connected to a second node;
a second transistor connected to a data line, the second transistor including a gate electrode connected to a first sub-gate line, the second transistor receiving a data signal supplied from the data line in response to a first scan signal supplied from the first sub-gate line;
a third transistor including a gate electrode connected to a third sub-gate line, the third transistor switching electrical connection between the first node and the second node in response to a third scan signal supplied from the third sub-gate line;
a fourth transistor including a gate electrode connected to a second sub-gate line, the fourth transistor switching electrical connection between the second node and a third power line in response to a second scan signal supplied from the second sub-gate line;
a fifth transistor including a gate electrode connected to an emission control line, the fifth transistor switching electrical connection between the first node and the light emitting element in response to an emission control signal supplied from the emission control line; and
a first capacitor including a first electrode connected to the first power line and a second electrode connected to the second node, wherein the second electrode is directly connected to the gate electrode of the first transistor, a semiconductor layer of the third transistor, and a semiconductor layer of the fourth transistor.

2. The sub-pixel of claim 1, wherein the semiconductor layer of the third transistor and the semiconductor layer of the fourth transistor are integrally formed.

3. The sub-pixel of claim 1, wherein the first to third sub-gate lines and the emission control line include a first metal layer extending in a first direction, and
wherein each of the first electrode of the first capacitor and the second electrode of the first capacitor includes the first metal layer.

4. The sub-pixel of claim 3, wherein the gate electrode of each of the first to fifth transistors includes a gate electrode layer,
wherein an interlayer insulating layer is interposed between the gate electrode layer and the first metal layer, and
wherein the first metal layer is directly connected to the gate electrode layer through a first contact portion formed in the interlayer insulating layer.

5. The sub-pixel of claim 3, wherein the first metal layer constituting the first electrode and the second electrode of the first capacitor extends in the first direction in an area overlapping with the gate electrode of the first transistor to face each other in a plan view, and
wherein the first electrode of the first capacitor and the second electrode of the first capacitor are interdigitated each other along the second direction.

6. The sub-pixel of claim 3, wherein the first power line, the third power line, and the data line include a second metal layer extending in a second direction, and
wherein each of the first electrode of the first capacitor and the second electrode of the first capacitor includes the second metal layer.

7. The sub-pixel of claim 6, wherein a first via layer is interposed between the first metal layer and the second metal layer, and
wherein the second metal layer is directly connected to the first metal layer at a second contact portion formed through the first via layer.

8. The sub-pixel of claim 6, wherein at least a portion of the second metal layer constituting the first capacitor overlaps at least a portion of the first metal layer constituting the first capacitor in a plan view.

9. The sub-pixel of claim 6, further comprising a second capacitor including one electrode connected to the second transistor and the other electrode connected to the second node,
wherein each of the one electrode of the second capacitor and the other electrode of the second capacitor includes a third metal layer located on the second metal layer.

10. The sub-pixel of claim 9, wherein each of the first electrode of the first capacitor and the second electrode of the first capacitor includes the third metal layer.

11. The sub-pixel of claim 10, wherein a second via layer is interposed between the second metal layer and the third metal layer, and
wherein the third metal layer is directly connected to the second metal layer at a third contact portion formed through the second via layer.

12. The sub-pixel of claim 11, wherein the third metal layer constituting the first electrode of the first capacitor is directly connected to the second metal layer constituting the first power line through the third contact portion.

13. The sub-pixel of claim 11, wherein the third metal layer constituting the second electrode of the first capacitor is directly connected to the second metal layer constituting the second node through the third contact portion.

14. The sub-pixel of claim 1, wherein the gate electrode of each of the first to fifth transistors includes a gate electrode layer, and
wherein the first to third sub-gate lines and the emission control line include the gate electrode layer extending in a first direction.

15. The sub-pixel of claim 14, wherein each of the first electrode of the first capacitor and the second electrode of the first capacitor includes a first metal layer,
wherein an interlayer insulating layer is interposed between the first metal layer and the gate electrode layer, and
wherein the first metal layer is directly connected to the gate electrode layer at a first contact portion formed through the interlayer insulating layer.

16. The sub-pixel of claim 15, wherein each of the first electrode of the first capacitor and the second electrode of the first capacitor overlaps with a semiconductor layer of each of the first to fifth transistors in a plan view.

17. A display device comprising:
a substrate; and
a plurality of sub-pixels disposed on the substrate, each of the plurality of sub-pixels includes:
a pixel circuit layer disposed on the substrate, the pixel circuit layer having a sub-pixel circuit of each of the plurality of sub-pixels; and
a light emitting element layer disposed on the pixel circuit layer, the light emitting element layer having a light emitting element of each of the plurality of sub-pixels,
wherein the pixel circuit layer includes:
a semiconductor layer;
a gate insulating layer disposed on the semiconductor layer;
a gate electrode layer disposed on the gate insulating layer;
an interlayer insulating layer disposed on the gate electrode layer, the interlayer insulating layer including a first contact portion; and
a first metal layer disposed on the interlayer insulating layer, the first metal layer being directly connected to the gate electrode layer through the first contact portion, the first metal layer constituting a capacitor included in the sub-pixel circuit.

18. The display device of claim 17, wherein the sub-pixel circuit includes:
a first transistor connected between a first power line and a first node, the first transistor including a gate electrode connected to a second node;
a second transistor connected to a data line, the second transistor including a gate electrode connected to a first sub-gate line, the second transistor receiving a data signal supplied from the data line in response to a first scan signal supplied from the first sub-gate line;
a third transistor including a gate electrode connected to a third sub-gate line, the third transistor switching electrical connection between the first node and the second node in response to a third scan signal supplied from the third sub-gate line;
a fourth transistor including a gate electrode connected to a second sub-gate line, the fourth transistor switching electrical connection between the second node and a third power line in response to a second scan signal supplied from the second sub-gate line;
a fifth transistor including a gate electrode connected to an emission control line, the fifth transistor switching electrical connection between the first node and the light emitting element in response to an emission control signal supplied from the emission control line; and
the capacitor including a first electrode connected to the first power line and a second electrode connected to the second node, wherein the second electrode is directly connected to the gate electrode of the first transistor, a semiconductor layer of the third transistor, and a semiconductor layer of the fourth transistor.

19. The display device of claim 18, wherein the gate electrode of each of the first to fifth transistors includes a gate electrode layer,
wherein a first sub-pixel and a second sub-pixel among the plurality of sub-pixels are located adjacent to each other in a first direction, and
wherein the gate electrode layer extends in the first direction to be commonly connected to the first sub-pixel and the second sub-pixel.

20. The display device of claim 19, further comprising a gate driving circuit configured to supply scan signals to the first to third sub-gate lines, and supply an emission control signal to the emission control line,
wherein the gate electrode layer is directly connected to the gate driving circuit.
